(19) United States
(12) Patent Application Publication
(10) Pub. No.: US 2020/0401047 A1
(43) Pub. Date: Dec. 24, 2020

(54) UNDERLAYER FILM-FORMING COMPOSITION, PATTERN-FORMING METHOD, COPOLYMER, AND MONOMER FOR UNDERLAYER FILM-FORMING COMPOSITION

(71) Applicant: OJI HOLDINGS CORPORATION, Tokyo (JP)

(72) Inventors: Kimiko HATTORI, Tokyo (JP); Kazuyo MORITA, Tokyo (JP)

(73) Assignee: OJI HOLDINGS CORPORATION, Tokyo (JP)

(21) Appl. No.: 16/975,565

(22) PCT Filed: Feb. 25, 2019
(86) PCT No.: PCT/JP2019/006950

§ 371 Date: Aug. 25, 2020

(30) Foreign Application Priority Data
Feb. 26, 2018 (JP) 2018-032283
Jul. 19, 2018 (JP) 2018-135614

(51) Int. Cl. G03F 7/11; G03F 7/09; C08L 1/02; C08L 33/08; G03F 7/004

(52) U.S. Cl. CPC G03F 7/11; G03F 7/091; G03F 7/0047; C08L 33/08; C08L 1/02

(57) ABSTRACT

An object of the present invention is to provide an underlayer film-forming composition capable of forming an underlayer film which remains with a high proportion in an organic solvent, has a low UV reflectivity, and is excellent in etching resistance. The present invention relates to an underlayer film-forming composition, which contains a copolymer and an organic solvent and is used for patterning, wherein the copolymer contains: (a) a unit derived from a sugar derivative; (b) a unit derived from a compound having a light antireflection function; and (c) a unit derived from a compound capable of cross-coupling the copolymer, the unit derived from a sugar derivative (a) is at least one selected from a unit derived from a pentose derivative and a unit derived from a hexose derivative, and the underlayer film-forming composition is used for metal introduction.

### TECHNICAL FIELD

The present invention relates to an underlayer film-forming composition, a pattern-forming method, a copolymer, and a monomer for an underlayer film-forming composition.

### BACKGROUND ART

Electronic devices such as semiconductors are required to be highly integrated due to miniaturization. Regarding the patterns of semiconductor devices, miniaturization and diversification of shapes are being studied. Known methods for forming such a pattern include a lithography method using a photoresist and a pattern-forming method involving self-assembly using directed self-assembly materials. For example, a lithography method using a photoresist is a processing method in which a photoresist pattern is obtained by forming a photoresist thin film is formed on a semiconductor substrate such as a silicon wafer, irradiating an actinic ray such as an ultraviolet ray through a mask pattern on which a pattern of a semiconductor device is drawn, and performing development, and then, fine irregularities corresponding to the pattern are formed on the substrate by etching the substrate with the obtained photoresist pattern as a protective film.

In order to form a fine pattern, a method for forming a pattern after forming an underlayer film on a substrate such as a silicon wafer has also been studied. For example, Patent Literature 1 discloses a composition for forming a resist underlayer film, which contains polysiloxane [A] and a solvent [B], and the solvent [B] contains a tertiary alcohol (B1). Patent Literature 2 discloses a method for forming a resist underlayer film, comprising a coating step of coating a composition for forming a resist underlayer film on a substrate, and a heating step of heating the obtained coating film in an atmosphere having an oxygen concentration of less than 1% by volume at a temperature higher than 450° C. to 800° C., wherein the composition for forming a resist underlayer film contains a compound having an aromatic ring.

In addition, Patent Literature 3 discloses an underlayer film-forming composition containing a dextrin ester compound obtained by esterifying 50% or more of dextrin, a crosslinkable compound, and an organic solvent. Patent Literature 4 discloses an underlayer film-forming composition for lithography containing cyclodextrin containing inclusion molecules.

### CITATION LIST

### Patent Literature

Patent Literature 1: JP Patent Publication No. 2016-170338 A

Patent Literature 2: JP Patent Publication No. 2016-206676 A

Patent Literature 3: WO2005/043248

Patent Literature 4: JP Patent Publication No. 2007-256773 A

### SUMMARY OF INVENTION

### Technical Problem

After a coating film formed from an underlayer film-forming composition is heated to form an underlayer film, the underlayer film must become difficult to dissolve in an organic solvent contained in a resist-forming composition (i.e., a material used for the underlayer film-forming composition has a high proportion of the residual underlayer film). However, the proportion of the residual underlayer film for an underlayer film formed by using a conventional underlayer film-forming composition cannot be said to be sufficiently high.

After a pattern is formed on an underlayer film, an etching step may be provided to process the pattern shape on a silicon wafer substrate using the pattern as a protective film. However, a protective film formed by using a conventional underlayer film-forming composition has insufficient etching resistance, and the pattern workability of the substrate remains problematic. Further, when forming a pattern on an underlayer film, a pattern may be formed by a resist. However, an underlayer film formed by using a conventional underlayer film-forming composition may have a high UV reflectivity, and there is a problem in maintaining the pattern shape when forming a resist pattern by exposure.

Therefore, in order to solve the problems of the prior art, the present inventors have conducted studies for the purpose of providing an underlayer film-forming composition capable of forming an underlayer film which remains with a high proportion in an organic solvent, has a low UV reflectivity, and is excellent in etching resistance.

### Solution to Problem

As a result of assiduous studies made for the purpose of solving the above-mentioned problems, the present inventors have found that an underlayer film which remains with a high proportion in an organic solvent, has a low UV reflectivity, and is excellent in etching resistance can be formed by using, as a material for an underlayer film-forming composition, a copolymer containing: (a) a unit derived from a sugar derivative; (b) a unit derived from a compound having a light antireflection function; and (c) a unit derived from a compound capable of cross-coupling the copolymer. This has led to the completion of the present invention.

Specifically, the present invention has the following constitution.

[1] An underlayer film-forming composition, which contains a copolymer and an organic solvent and is used for patterning,

wherein the copolymer contains:

(a) a unit derived from a sugar derivative;

(b) a unit derived from a compound having a light antireflection function; and

(c) a unit derived from a compound capable of cross-coupling the copolymer,

the unit derived from a sugar derivative (a) is at least one selected from a unit derived from a pentose derivative and a unit derived from a hexose derivative, and

the underlayer film-forming composition is for metal introduction.

[2] The underlayer film-forming composition according to [1], wherein the unit derived from a compound having a light antireflection function (b) is a unit derived from an aromatic ring-containing compound, and the unit derived from a compound capable of cross-coupling the copolymer (c) is a unit derived from a (meth)acrylate.
[3] The underlayer film-forming composition according to [1] or [2], wherein the unit derived from a sugar derivative (a) is at least one selected from a unit derived from a cellulose derivative, a unit derived from a hemicellulose derivative, and a unit derived from a xylooligosaccharide derivative.
[4] The underlayer film-forming composition according to [2] or [3], wherein the unit derived from an aromatic ring-containing compound is at least one selected from a unit derived from a benzene ring-containing compound and a unit derived from a naphthalene ring-containing compound.
[5] The underlayer film-forming composition according to any one of [2] to [4], wherein the unit derived from a (meth)acrylate has at least one selected from an alkyl group which may have a substituent and an aryl group which may have a substituent.
[6] The underlayer film-forming composition according to any one of [2] to [5], wherein the unit derived from a (meth)acrylate has an alkyl group which may have a substituent, and the alkyl group has 1 to 8 carbon atoms.
[7] A pattern-forming method, comprising:

forming an underlayer film using the underlayer film-forming composition according to any one of [1] to [6].

[8] The pattern-forming method according to [7], comprising:

introducing a metal into the underlayer film.

[9] A copolymer containing: (a) a unit derived from a sugar derivative;

(b) a unit derived from a compound having a light antireflection function; and

(c) a unit derived from a compound capable of cross-coupling the copolymer,

wherein the unit derived from a sugar derivative (a) is at least one selected from a unit derived from a pentose derivative and a unit derived from a hexose derivative.

[10] The copolymer according to [9], wherein the unit derived from a compound having a light antireflection function (b) is a unit derived from an aromatic ring-containing compound, and the unit derived from a compound capable of cross-coupling the copolymer (c) is a unit derived from a (meth)acrylate.
[11] A monomer for an underlayer film-forming composition, which is represented by the following formula (1′) or the following formula (2′):

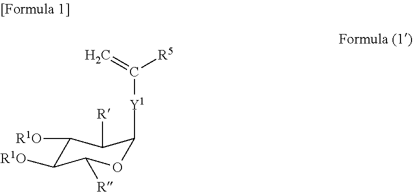

wherein, in formula (1′), each R independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R¹ may be the same or different;

R′ represents a hydrogen atom, —OR¹¹, or —NR¹²₂:

R″ represents a hydrogen atom, —OR¹¹, —COOR³, or —CH₂OR¹³, provided that R¹¹ represents a hydrogen atom, an alkyl group, an acyl group, an aryl group, a trimethylsilyl group, or a phosphoryl group, R¹ represents a hydrogen atom, an alkyl group, a carboxyl group, or an acyl group, a plurality of R¹ may be the same or different, and R¹³ represents a hydrogen atom, an alkyl group, an acyl group, an aryl group, a trimethylsilyl group, or a phosphoryl group;

R⁵ represents a hydrogen atom or an alkyl group; and

each Y¹ independently represent a single bond or a linking group;

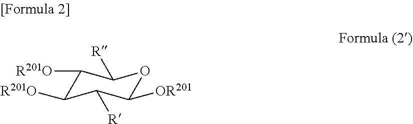

wherein, in formula (2′), each R²⁰³ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different;

R′ represents a hydrogen atom, —OR¹¹, or —NR¹²₂; and

R″ represents a hydrogen atom, —OR¹¹, —COOR³, or —CH²OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group.

### Advantageous Effects of Invention

According to the present invention, an underlayer film which remains with a high proportion in an organic solvent, has a low UV reflectivity, and is excellent in etching resistance can be formed.

### BRIEF DESCRIPTION OF DRAWINGS

FIG. 1 is a cross-sectional view for illustrating an example of a structure composed of a substrate and an underlayer film.

### DESCRIPTION OF EMBODIMENTS

The present invention is described in detail hereinunder. The description of the constitutive elements of the invention given hereinunder is for some typical embodiments and examples of the invention, but the invention should not be limited to such embodiments. In this description, the numerical range expressed by the wording “a number to another number” means the range that falls between the former number indicating the lower limit value of the range and the latter number indicating the upper limit value thereof.

In addition, with regard to a substituent described herein for which substitution/non-substitution is not specified, it means that the group may have an arbitrary substituent. Moreover, the term “(meth)acrylate” used herein is meant to include both “acrylate” and “methacrylate.”

### (Underlayer Film-Forming Composition)

The present invention relates to an underlayer film-forming composition which contains a copolymer and an organic solvent and is used for patterning. The copolymer contains: (a) a unit derived from a sugar derivative; (b) a unit derived from a compound having a light antireflection function; and (c) a unit derived from a compound capable of cross-coupling the copolymer. The unit derived from a sugar derivative (a) is at least one selected from a unit derived from a pentose derivative and a unit derived from a hexose derivative, and the underlayer film-forming composition is for metal introduction.

The underlayer film-forming composition of the present invention can form an underlayer film which remains with a high proportion in an organic solvent, has a low UV reflectivity, and is excellent in etching resistance. Since an underlayer film formed from the underlayer film-forming composition of the present invention has a low UV reflectivity, a pattern can be formed accurately when forming a resist film on the underlayer film and performing light exposure to form a pattern, making it easy to maintain the pattern shape. In addition, since an underlayer film formed from the underlayer film-forming composition of the present invention has excellent etching resistance, etching workability of a substrate or the like can be improved. Further, a copolymer contained in the underlayer film-forming composition of the present invention includes a plurality of constitutional units as described above, which is therefore characterized in that the copolymer is highly soluble in an organic solvent while the copolymer remains after being cured into the underlayer film without being dissolved in an organic solvent contained in a resist-forming composition or the like.

The unit derived from a sugar derivative of the copolymer (hereinafter, also referred to as “unit (a)”) contains a large number of crosslinking reaction sites, and thus tends to promote crosslinking by heating (regardless of the addition of a crosslinking agent). Therefore, it is possible to increase the proportion of the residual underlayer film after an underlayer film is formed by heat-treating a coating film. That is to say, after a coating film formed from an underlayer film-forming composition is heat-treated to form an underlayer film, the solubility of the copolymer in an organic solvent can be lowered. Further, since the copolymer has the unit (a), etching workability can be improved.

The proportion of the residual underlayer film is preferably 90% or more, more preferably 93% or more, and even more preferably 95% or more. Here, the proportion of the residual underlayer film is a value calculated by the following equation based on the underlayer film thickness before and after applying a 50:50 (mass ratio) mixture of propylene glycol monomethyl ether acetate and propylene glycol monomethyl ether, which is a solvent used for photoresist, to an underlayer film (before and after washing).

Proportion of residual underlayer film (%)=Underlayer film thickness after washing (μm)/Underlayer film thickness before washing (μm)*100

The etching workability can be evaluated by the following method. First, an underlayer film-forming composition is applied to a silicon substrate to form an underlayer film, and then the underlayer film is formed into a line-and-space pattern shape, and etching is performed on the silicon substrate. Then, the patterned surface of the silicon substrate is observed with a scanning electron microscope to confirm the etching workability. If the pattern shape of the silicon substrate is in a state in which there is no line collapse in one visual field of the scanning electron microscope, it can be determined that the etching workability is favorable.

Further, in the underlayer film-forming composition of the present invention, since the copolymer has the unit (a), a large amount of a metal can be introduced into the underlayer film. Therefore, it can be said that the underlayer film-forming composition of the present invention is a material for introducing a metal. The copolymer contained in the underlayer film-forming composition reacts (bonds) to a metal such that an underlayer film containing the metal can be formed. Such an underlayer film becomes harder than an underlayer film containing no metal, and thus, it can exhibit excellent etching workability. Here, it is preferable that the copolymer contained in the underlayer film-forming composition reacts (bonds) with a metal at a plurality of sites in one molecule of the copolymer, and the more the number of sites for reacting (bonding) with the metal, the higher the metal introduction rate. In the present invention, the metal introduction rate is increased by reacting (bonding) oxygen atoms and metal atoms contained in the copolymer, and such a high metal introduction rate is achieved by allowing the copolymer to have the unit (a). The bonding between oxygen atoms and metal atoms contained in the copolymer is not particularly limited, but for example, the bonding between oxygen atoms and metal atoms contained in the copolymer is preferably coordinate bonding or ionic bonding.

The metal introduction rate in the underlayer film is preferably 5 at % (atomic percent) or more, more preferably 8 at % or more, even more preferably 10 at % or more, and particularly preferably 15 at % or more. The metal introduction rate can be calculated, for example, by the following method. First, an underlayer film formed from the underlayer film-forming composition is placed in an atomic layer deposition apparatus (ALD), and Al(CH₃)₃ gas is introduced therein at 95° C., and then steam is introduced. By repeating this operation three times, Al is introduced into the underlayer film EDX analysis (energy dispersive X-ray analysis) is performed on the underlayer film after introduction of Al by using an electron microscope JSM7800F (manufactured by JEOL Ltd.) to calculate an Al component ratio (Al content), which is used as a metal introduction rate.

The unit derived from a compound having a light antireflection function contained in the copolymer (hereinafter, also referred to as “unit (b)”) has a property of absorbing light. Regarding the light antireflection function of the unit (b), a coating film having a thickness of 0.1 μm is formed from a coating liquid comprising a monomer of the unit (b) and a solvent, and the coating film is exposed to UV rays (for example, UV ray s having a wavelength of 193 nm). When the reflectivity is 30% or less, the unit (b) can be evaluated to have a light antireflection function. The reflectivity of the coating film can be evaluated by measuring it with a spectrophotometer. As a spectrophotometer, for example, V770EX manufactured by JASCO Corporation can be used, and it is preferable to perform the measurement with an integrating sphere installed in the spectrophotometer. In a case where a coating film cannot be formed from a monomer of the unit (b), a coating film may be formed from a coating liquid containing the polymer composed of the unit (b).

Since the copolymer has the unit (b), the underlayer film formed from the underlayer film-forming composition can exhibit a light antireflection function. Therefore, a pattern shape can be formed accurately when forming a resist film on the underlayer film and performing light exposure to form a pattern. The light antireflection function of the underlayer film can be evaluated by irradiating the underlayer film with UV rays (for example, UV rays having a wavelength of 193 nm) and measuring the reflectivity with a spectrophotometer. As a spectrophotometer, for example, V770EX manufactured by JASCO Corporation can be used, and it is preferable to perform the measurement with an integrating sphere installed in the spectrophotometer. The UV reflectivity (light reflectivity) of the underlayer film is preferably 50% or less, more preferably 30% or less, and even more preferably 20% or less.

Furthermore, since the copolymer has a unit derived from a compound capable of cross-coupling the copolymer (hereinafter, also referred to as “unit (c)”), the cross-coupling reaction of the copolymer can be promoted. Cross-coupling means that the copolymer in the underlayer film-forming composition is bound by heating or photoreaction, or the functional group in the copolymer is bound. Accordingly, the proportion of the residual underlayer film in an organic solvent can be increased, and the etching workability can be further improved. Further, since the copolymer has the unit (c), an underlayer film which is not easily broken by heat treatment in the air and at a relatively low temperature can be formed. For example, even in a case where the underlayer film is placed under severe conditions such as high temperature conditions, cracking is suppressed.

The presence or absence of the unit (c) in the copolymer can be determined by detecting the change in the peak of a functional group before and after curing the underlayer film-forming composition by FT-IR. For example, when the compound capable of cross-coupling the copolymer is glycidyl methacrylate, the copolymer is cross-coupled by curing the underlayer film-forming composition, a peak near 916 cm⁻¹ disappears, and a peak derived from an ether group near 1106 cm⁻¹ and a peak derived from a hydroxyl group near 3160 to 3600 cm⁻¹ are detected. Thus, it can be evaluated that cross-coupling of the copolymer has occurred. Specifically, for example, in a case where the unchanged peak height of a methyl group is used as the peak height of a reference functional group, the cross-coupling reaction rate is calculated from the ratio of the peak height lost by cross-coupling, and the cross-coupling reaction rate is 95% or less, it can be determined that cross-coupling of the copolymer has occurred, that is to say, the copolymer contains a unit (c).

Cross-coupling reaction rate (%)=(Peak height of functional group derived from cross-coupling group after curing/Peak height of reference functional group)/(Peak height of functional group derived from cross-coupling group before curing/Peak height of reference functional group)*100

The underlayer film formed from the underlayer film-forming composition of the present invention is, for example, a film (protective film) provided on a substrate for forming a pattern on a substrate such as a silicon wafer. The underlayer film may be a film provided on the substrate so as to be in direct contact therewith, or may be a film laminated on the substrate via another layer. The underlayer film is processed into a pattern shape which is desired to be formed on the substrate, and the portion left as the pattern shape serves as a protective film in the subsequent etching step. Then, after the pattern is formed on the substrate, the underlayer film (protective film) is usually removed from the substrate. Thus, the underlayer film is used in the step of forming a pattern on the substrate.

The underlayer film formed from the underlayer film-forming composition of the present invention exhibits excellent etching resistance when processing a pattern shape on a substrate, and the etching resistance of such an underlayer film can be evaluated based on, for example, an etching selectivity calculated by the following equation.

Etching selectivity=Maximum depth of etched portion of substrate/(Average thickness of underlayer film before etching treatment−Average thickness of underlayer film after etching treatment)

The depth of the etched portion of the substrate and the thickness of the underlayer film before and after the etching treatment can be measured by, for example, observing a cross section of the substrate with a scanning electron microscope (SEM). The depth of the etched portion of the substrate is the maximum depth of the portion cut by etching treatment, and the thickness of the underlayer film before and after the etching treatment is the maximum thickness of the remaining portion of the underlayer film. The etching selectivity calculated as described above is preferably greater than 1.5, more preferably 2 or more, still more preferably 3 or more, and even more preferably 4 or more The upper limit of the etching selectivity is not particularly limited, but can be set to 200, for example.

Further, the underlayer film-forming composition of the present invention may be used as a material for forming a photomask for forming a pattern. A photomask is formed by forming a predetermined pattern on a photomask substrate and performing steps such as etching and resist stripping.

### <Copolymer>

The underlayer film-forming composition of the present invention contains a copolymer. The copolymer contains a unit (a), a unit (b), and a unit (c). Here, the unit (a) is a unit derived from a sugar derivative, the unit (b) is a unit derived from a compound having a light antireflection function, and the unit (c) is a unit derived from a compound capable of cross-coupling the copolymer. The unit (a) is at least one selected from a unit derived from a pentose derivative and a unit derived from a hexose derivative. The present invention may also relate to a copolymer containing a unit (a), a unit (b), and a unit (c).

The copolymer may be a block copolymer or a random copolymer. Further, the copolymer may have a structure which partially includes a random copolymer and partially includes a block copolymer. The copolymer is preferably a block copolymer from the viewpoint of increasing solubility in an organic solvent, and a random copolymer is preferable from the viewpoint of promoting crosslinking and increasing strength. Therefore, an appropriate structure can be selected as appropriate depending on the application and required physical properties.

In a case where the copolymer is a block copolymer, it is preferably an A-B-C type diblock copolymer containing a polymerized portion a comprising units (a), a polymerized portion b comprising units (b), and a polymerized portion c comprising units (c), but it may be a block copolymer containing a plurality of polymerized portions a, polymerized portions b, and polymerized portions c (e.g., A-B-C-A-B-C type).

The content of the copolymer is preferably 0.1% by mass or more, and more preferably 1% by mass or more with respect to the total mass of the underlayer film-forming composition. In addition, the content of the copolymer is preferably 90% by mass or less, more preferably 80% by mass or less, and even more preferably 70% by mass or less with respect to the total mass of the underlayer film-forming composition.

The copolymer preferably consists of an organic material. This is preferable from the viewpoint of favorable adhesion to an organic resist material or the like as compared with the case where the copolymer contains an organic-inorganic hybrid material such as polysiloxane.

### (Unit (a))

The unit (a) is a unit derived from a sugar derivative (a), and the unit derived from a sugar derivative is at least one selected from a unit derived from a pentose derivative and a unit derived from a hexose derivative. A structure which easily allows for coordinating to a metal is formed by introducing, as the unit (a) of the copolymer, a unit derived from a sugar derivative having many oxygen atoms as described above, and a metal can be introduced into either one of the copolymer, the underlayer film-forming composition, and the underlayer film formed from the underlayer film-forming composition by a simple method such as a sequential infiltration synthesis method. As a result, etching workability can be improved. The metal-introduced underlayer film as described above can serve as a higher performance mask in the lithography process.

The sugar derivative may be a monosaccharide-derived sugar derivative, or it may have a structure in which a plurality of monosaccharide-derived sugar derivatives are bound to each other. In a case where the copolymer is a block copolymer, the polymerized portion a comprising the unit (a) has a structure in which a plurality of monosaccharide-derived sugar derivatives are bound to each other.

The unit derived from a sugar derivative is at least one selected from a unit derived from a pentose derivative and a unit derived from a hexose derivative.

The pentose derivative is not particularly limited as long as it has a pentose-derived structure in which the hydroxyl group of pentose of a known monosaccharide or polysaccharide is modified with at least a substituent. The pentose derivative is preferably at least one selected from a hemicellulose derivative, a xylose derivative, and a xylooligosaccharide derivative, and more preferably at least one selected from a hemicellulose derivative and a xylooligosaccharide derivative.

The hexose derivative is not particularly limited as long as it has a hexose-derived structure in which the hydroxyl group of hexose of a known monosaccharide or polysaccharide is modified with at least a substituent. The hexose derivative is preferably at least one selected from a glucose derivative and a cellulose derivative, and more preferably a cellulose derivative.

Above all, the unit derived from a sugar derivative (unit (a)) is preferably at least one selected from a unit derived from a cellulose derivative, a unit derived from a hemicellulose derivative, and a unit derived from a xylooligosaccharide derivative. Above all, the polymer more preferably contains a unit derived from a xylooligosaccharide derivative because the oxygen atom content in the molecule is high and the number of metal-binding sites is large.

The unit derived from a sugar derivative may be a constitutional unit having a sugar derivative-derived structure in its side chain or may be a constitutional unit having a sugar derivative-derived structure in its main chain. In a case where the unit derived from a sugar derivative is a constitutional unit having a sugar derivative-derived structure in its side chain, the unit derived from a sugar derivative preferably has a structure represented by the formula (1) described later. Also in a case where the unit derived from a sugar derivative is a constitutional unit having a sugar derivative-derived structure in its main chain, the unit derived from a sugar derivative preferably has a structure represented by the formula (2) described later. Above all, the unit derived from a sugar derivative preferably has a structure represented by the formula (1) from the viewpoint that its main chain is not excessively long and the solubility of the copolymer in an organic solvent is easily increased. Note that, in the formulae (1) and (2), the structure of a sugar derivative is described as a cyclic structure, but the structure of a sugar derivative is not limited to a cyclic structure and may be an open ring structure (chain structure) called aldose or ketose.

The structure represented by the formula (1) will be described below.

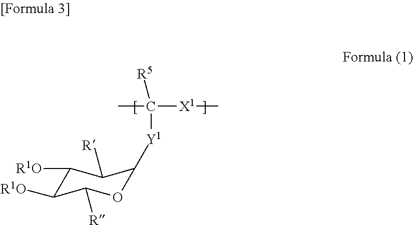

wherein, in the formula (1), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different.

R′ represents a hydrogen atom, —OR¹¹, or —NR¹²₂.

R″ represents a hydrogen atom, —OR¹¹, —COOR¹³, or —CH₂OR¹³. R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

R⁵ represents a hydrogen atom or an alkyl group.

X¹ and Y¹ each independently represent a single bond or a linking group.

In the formula (1), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different. Above all, it is preferable that each R¹ is independently a hydrogen atom or an acyl group having 1 to 3 carbon atoms. In a case where the above-described alkyl group is an alkyl group having a substituent, since such an alkyl group includes a sugar derivative group, its sugar chain portion may further have a unit derived from a linear or branched sugar derivative.

The unit derived from a linear or branched sugar derivative is preferably a sugar derivative having the same structure as the sugar derivative to be bonded. Specifically, in a case where R″ in the structure represented by the formula (1) is a hydrogen atom, —OR¹¹, a carboxyl group, or —COOR¹³, and its sugar chain portion (sugar derivative) further has a unit derived from a linear or branched sugar derivative, the unit preferably has a unit derived from a pentose derivative. In a case where R″ of the structure represented by the formula (1) is —CH₂OR¹³, and its sugar chain portion (sugar derivative) further has a unit derived from a linear or branched sugar derivative, the unit preferably has a unit derived from a hexose derivative. A substituent that the hydroxyl group of a unit derived from a linear or branched sugar derivative may further have can be the same as the range of R¹.

In the formula (1), R¹ further has a sugar derivative group as at least one alkyl group, meaning that it forms a structure in which a plurality of units derived from a monosaccharide-derived sugar derivative are bonded to each other, which is preferable from the viewpoint of lowering the solubility in an organic solvent. In this case, the average degree of polymerization of the sugar derivative (which means the number of monosaccharide-derived sugar derivatives bonded) is preferably 1 to 20, more preferably 15 or less, and even more preferably 12 or less.

In a case where R¹ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less.

Specific examples of R¹ include: acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and an acetyl group and a propanoyl group are particularly preferable.

In the formula (1), R′ represents a hydrogen atom, —OR¹¹, or —NR¹²₂, R¹¹ represents a hydrogen atom, an alkyl group, an acyl group, an aryl group, a trimethylsilyl group, or a phosphoryl group. In a case where R¹¹ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less. Above all, R¹¹ is preferably a hydrogen atom, an alkyl group having 1 to 3 carbon atoms, or an acyl group or a trimethylsilyl group having 1 to 3 carbon atoms. Specific examples of R¹¹ include: acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and a methyl group, an acetyl group and a propanoyl group are particularly preferable.

R¹² represents a hydrogen atom, an alkyl group, a carboxyl group, or an acyl group, and a plurality of R¹² may be the same or different. Above all, R¹² is preferably a hydrogen atom or an alkyl group having 1 to 3 carbon atoms, or a carboxyl group or —COCH₃.

A preferable structure of R′ is —H, —OH, —OAc, —OCOC₂H₅, —OCOC₆H₅, —NH₂, —NHCOOH, or —NHCOCH₃, a more preferable structure of R′ is —H, —OH, —OAc, —OCOC₂H₅, or —NH₂, and a particularly preferable structure of R′ is —OH, —OAc, or —OCOC₂H₅

In the formula (1), R″ represents, a hydrogen atom, —OR¹¹, a carboxyl group, —COOR¹³, or —CH₂OR¹³. R¹³ represents a hydrogen atom, an alkyl group, an acyl group, an aryl group, a trimethylsilyl group, or a phosphoryl group. In a case where¹³ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less. Above all, R¹³ is preferably a hydrogen atom, or, an alkyl group, an acyl group or a trimethylsilyl group having 1 to 3 carbon atoms.

Specific examples of R¹¹ include, acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and an acetyl group and a propanoyl group are particularly preferable.

A preferable structure of R^{H} is —H, —OAc, —OCOC₂H₅, —COOH, —COOCH₃, —COOC₂H₅, —CH₂OH, —CH₂OAC, or —CH₂OCOC₂H₅, a more preferable structure of R″ is —H, —OAc, —OCOC₂H₅, —COOH, —CH₂OH, —CH₂OAC, or —CH₂OCOC₂H₅, and a particularly preferable structure of R″ is —H, —CH₂OH, or —CH₂OAc.

In the formula (1). R⁵ represents a hydrogen atom or an alkyl group. Above all. R⁵ is preferably a hydrogen atom or an alkyl group having 1 to 3 carbon atoms, and particularly preferably a hydrogen atom or a methyl group.

In the formula (1), X¹ and Y¹ each independently represent a single bond or a linking group.

In a case where X¹ is a linking group, examples of X¹ include groups such as an alkylene group, —O—, —NH₂—, and a carbonyl group, while X¹ is preferably a single bond or an alkylene group having 1 to 6 carbon atoms, and more preferably an alkylene group having 1 to 3 carbon atoms.

In a case where Y¹ is a linking group, examples of Y¹ include groups such as an alkylene group, a phenylene group, —O—, and —C(═O)O—. Y¹ may be a linking group formed by combining these groups. Above all, Y¹ is preferably a linking group represented by the following structural formula.

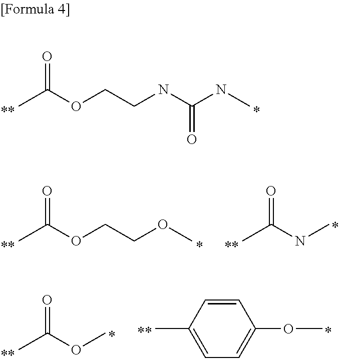

In the above structural formula, a double asterisk (**) indicates the binding site to the main chain side, and a single asterisk (*) indicates the binding site to the sugar unit on the side chain.

The structure represented by the formula (2) will be described below.

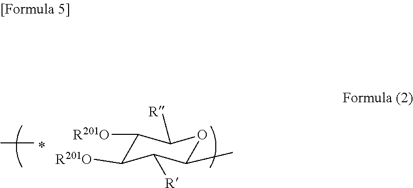

wherein, in the formula (2), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different:

R′ represents a hydrogen atom, —OR¹¹, or —NR¹²₂.

R″ represents a hydrogen atom. —OR¹¹, —COOR¹³, or —CH₂OR¹³. R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

The asterisk (*) represents a binding site with any one of oxygen atoms to which R²⁰¹ is bound, instead of R²⁰¹.

In the formula (2), preferable ranges of R²⁰¹, R′, and R″ are the same as the preferable ranges of R¹, R′ and R″ in the formula (1).

In addition, R¹, R′, and R″ can be returned to hydrogen atoms by reduction from the poly mer after polymerization, and thus, R¹ and R¹¹ can be hydrogen. However, R¹ and R¹¹ may not all be reduced.

### (Unit (b))

The unit (b) is a unit derived from a compound having a light antireflection function. In the present invention, the compound having a light antireflection function is preferably a compound having a property of strongly absorbing UV rays, such as an aromatic ring-containing compound.

In a case where the compound having a light antireflection function is an aromatic ring-containing compound, the unit (b) is a unit that exhibits hydrophobicity as compared with the unit (a), and thus the unit (a) functions to increase the solubility of the copolymer, which is the material of the underlayer film-forming composition, in an organic solvent. That is to say, in the underlayer film-forming composition, undissolved residues of the copolymer are prevented from being generated. It is also preferable that the unit (b) is a unit derived from an aromatic ring-containing compound from the viewpoint of easily increasing the proportion of the residual underlayer film in a case where an underlayer film is formed without unnecessarily affecting the crosslinkability. Thus, in a case where the compound having an antireflection function is an aromatic ring-containing compound, the copolymer contained in the underlayer film-forming composition has a high solubility in an organic solvent before film formation, but it can exhibit a property of becoming poorly soluble in the organic solvent after film formation.

Above all, the unit (b) is preferably at least one selected from a unit derived from a benzene ring-containing compound and a unit derived from a naphthalene ring-containing compound. The unit (b) is particularly preferably a unit derived from a benzene ring-containing compound.

The unit (b) is preferably, for example, a unit having a structure represented by the following formula (3) or (4).

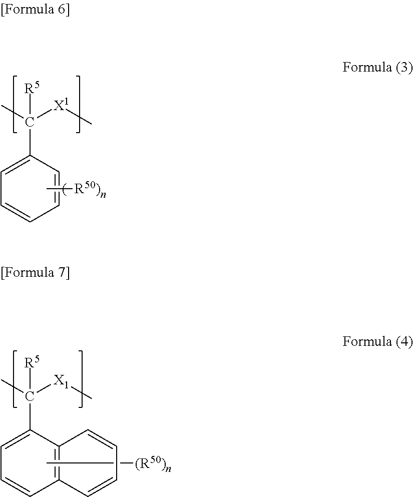

In the formulae (3) and (4), R⁵ represents a hydrogen atom or an alkyl group.

X¹ represents a single bond or a linking group.

R⁵⁰ represents an organic group or a hydroxyl group.

In the formula (3), n represents an integer of 0 to 5, and in the formula (4), n represents an integer of 0 to 7.

In the formulae (3) and (4), preferable ranges of R⁵ and X¹ are the same as the preferable ranges of R⁵ and X¹ in the formula (1).

In the formulae (3) and (4), in a case where R⁵⁰ is an organic group, R⁵⁰ is preferably a hydrocarbon group which may have a substituent, which is preferably an alkyl group which may have a substituent. Examples of a hydrocarbon group which may have a substituent can also include those in which any of the carbon atoms constituting the hydrocarbon group is replaced with an oxygen atom, a silicon atom a nitrogen atom, a sulfur atom a halogen, or the like. For example, R⁵⁰ may be a trimethylsilyl group, a pentamethyldisilyl group, a trifluoromethyl group, or a pentafluoroethyl group.

In the formula (3), n represents an integer from 0 to 5, preferably an integer of 0 to 3, and particularly preferably 0. In addition, in the formula (4), n represents an integer of 0 to 7, preferably an integer of 0 to 5, more preferably an integer of 0 to 3, and particularly preferably 0.

### (Unit (c))

The unit (c) is a unit derived from a compound capable of cross-coupling the copolymer. In the present invention, the unit derived from the compound capable of cross-coupling the copolymer is preferably a unit derived from a (meth)acrylate.

The unit derived from a (meth)acrylate is preferably, for example, a unit represented by the following formula (5).

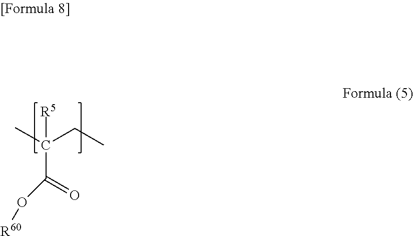

In formula (5), R⁵ represents a hydrogen atom or an alkyl group, and R⁶⁰ represents an alkyl group which may have a substituent or an aryl group which may have a substituent.

In the formula (5), R⁵ is preferably a hydrogen atom or an alkyl group having 1 to 3 carbon atoms, and particularly preferably a hydrogen atom or a methyl group.

The unit (c) preferably has at least one selected from an alkyl group which may have a substituent and an aryl group which may have a substituent. That is to say, in the formula (5), R⁶⁰ represents an alkyl group which may have a substituent or an aryl group which may have a substituent. In addition, R⁶⁰ may be a group in which the above groups are combined.

Above all, the unit (c) preferably contains an alkyl group which may have a substituent. That is to say, R⁶⁰ is preferably an alkyl group which may have a substituent. The alkyl group preferably has 1 to 8 carbon atoms, more preferably 1 to 5 carbon atoms, and even more preferably 1 to 3 carbon atoms. In addition, R⁶⁰ is also preferably an alkyl group having no substituent, and the above-described number of carbon atoms is a number of carbon atoms excluding the substituent.

Examples of a substituent which an alkyl group having a substituent may have can include an isocyanate group, an epoxy group, a (meth)acryloyl group, a hydroxy methylamino group, and an alkoxymethylamino group. Such a substituent may be a cross-coupling group or may be a group which forms a cross-coupling structure by self-condensation of a copolymer alone by heating or by a crosslinking reaction in the presence of a catalyst or the like. For example, in an alkyl group having an epoxy group as a substituent, a ring-opening reaction of the epoxy group occurs in the presence of an acid catalyst, which causes a crosslinking reaction. In this case, the above-described unit (c) can strengthen the formed underlayer film by a crosslinking reaction.

Examples of an alkyl group having a substituent may include —CH₂—OH, —CH₂—O-methyl, —CH₂—O-ethyl, —CH₂—O-n-propyl, —CH₂—O-isopropyl, —CH₂—O-n-butyl, —CH₂—O— isobutyl, —CH₂—O-t-butyl, —CH₂—O—(C═O)-methyl, CH₂—O—(C═O)-ethyl. —CH₂—O—(CO)-propyl, —CH₂—O—(C═O)-isopropyl, —CH₂—O—(C═O)-n-butyl, —CH₂—O—(C═O)-isobutyl, —CH₂—O—(C═O)-t-butyl, —CH₂-ethylene oxide, —C₂H₄—OH, —C₂H₄—O-methyl, —C₂H₄—O-ethyl, —C₂H₄—O-n-propyl, —C₂H₄—O-isopropyl, —C₂H₄—O-n-butyl, —C₂H₄—O-isobutyl, —C₂H₄—O-t-butyl, —C₂H₄—O—(C═O)-methyl, —C₂H₄—O—(C═O)-ethyl, —C₂H₄—O—(C═O)-n-propyl, —C₂H₄—O—(C═O)-isopropyl, —C₂H₄—O—(C═O)-n-butyl, —C₂H₄—O—(CO)-isobutyl, —C₂H₄—O—(C═O)-t-butyl, —C₂H₄—O—(C═O)—CH₂—(C═O)-methyl, —C₂H₄-ethylene oxide, —C₃H₆-ethylene oxide, —C₂H₄—O-ethylene oxide, —C₃H₆—O-ethylene oxide, —C₄H₈—O-ethylene oxide, —C₅H₁₀—O-ethylene oxide, —CH₂—CH═CH₂, and —CH₂—O—CH═CH₂. The alkyl group having a substituent may be a cycloalkyl group or a crosslinked cyclic cycloalkyl group.

### (Content)

The content of the unit (a) in the copolymer (content of the sugar derivative unit) is preferably 1% by mass to 95% by mass, more preferably 5% by mass to 90% by mass, even more preferably 10% by mass to 85% by mass, and particularly preferably 20% by mass to 80% by mass with respect to the total mass of the copolymer.

Here, the content of the sugar derivative unit in the copolymer can be determined from, for example, ¹H-NMR and the weight average molecular weight of the copolymer. Specifically, it can be calculated using the following equation.

Content of unit (a) (% by mass)=Mass of unit (a)×Number of units (a) (number of monomers)/Weight average molecular weight of copolymer

The content of the unit (b) in the copolymer is preferably 1% by mass to 95% by mass, more preferably 5% by mass to 90% by mass or less, and even more preferably 10% by mass to 85% by mass with respect to the total mass of the copolymer. The content of the unit (c) in the copolymer is preferably 1% by mass to 95% by mass, more preferably 5% by mass to 90% by mass, and even more preferably 10% by mass to 85% by mass with respect to the total mass of the copolymer.

The content of each unit can also be calculated by the same method as the calculation of the content of the unit (a).

### (Other Constitutional Units)

The copolymer may have other constitutional units in addition to the above-described constitutional units. Examples of other constitutional units may include a lactic acid-derived unit, a siloxane bond-containing unit, an amide bond-containing unit, and a urea bond-containing unit.

### (Structure of Block Copolymer)

In a case where the copolymer is a block copolymer, it is preferably an A-B-C type block copolymer containing a polymerized portion a comprising units (a), a polymerized portion b comprising units (b), and a polymerized portion c comprising units (c), but it may be a block copolymer containing a plurality of polymerized portions a, polymerized portions b, and polymerized portions c (e.g., A-B-C-A-B-C type).

In the block copolymer, each polymerized portion may be linked by a linking group. Examples of such a linking group include —O—, an alkylene group, a disulfide group, and groups represented by the following structural formulae. In a case where the linking group is an alkylene group, a carbon atom in the alkylene group may be substituted with a hetero atom, and examples of the hetero atom include a nitrogen atom, an oxygen atom, a sulfur atom, and a silicon atom. The length of the linking group is preferably shorter than the length of each polymerized portion.

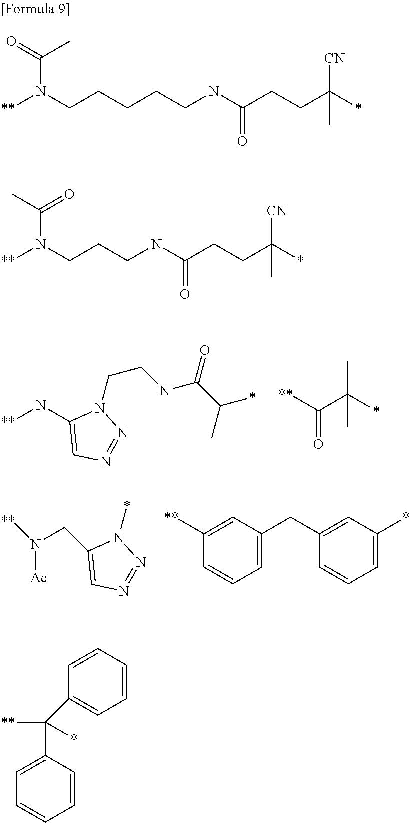

In the above structural formula, a single asterisk (*) and a double asterisk (**) each indicate the binding site to each polymerized portion.

Further, the terminal groups of the main chain of the block copolymer can be, for example, a hydrogen atom or a substituent. The terminal groups of the main chain may be the same or different. Examples of a substituent include: a fluorine atom, a chlorine atom, a bromine atom, an iodine atom; acyl groups such as a hydroxyl group, an amino group, an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, a propyl group, an n-butyl group, a sec-butyl group, a tert-butyl group, 2-methylbutyronitrile, a cyanovalerinoyl group, a cyclohexyl-1-carbonitrile group, a methylpropanoyl group, and an N-butyl-methylpropionamide group; substituents represented by the following structural formulae. The terminal groups of the main chain of the block copolymer are each independently preferably a hydrogen atom, a hydroxyl group, an acetyl group, a propanoyl group, a butyryl group, an isobutyryl group, an n-butyl group, a sec-butyl group, a tert-butyl group, a 2-methylbutyronitrile, a cyanovalerinoyl group, a cyclohexyl-1-carbonitrile group, a methylpropanoyl group or any of substituents shown below, and particularly preferably a hydrogen atom, a hydroxyl group, a butyl group, or any of substituents shown below.

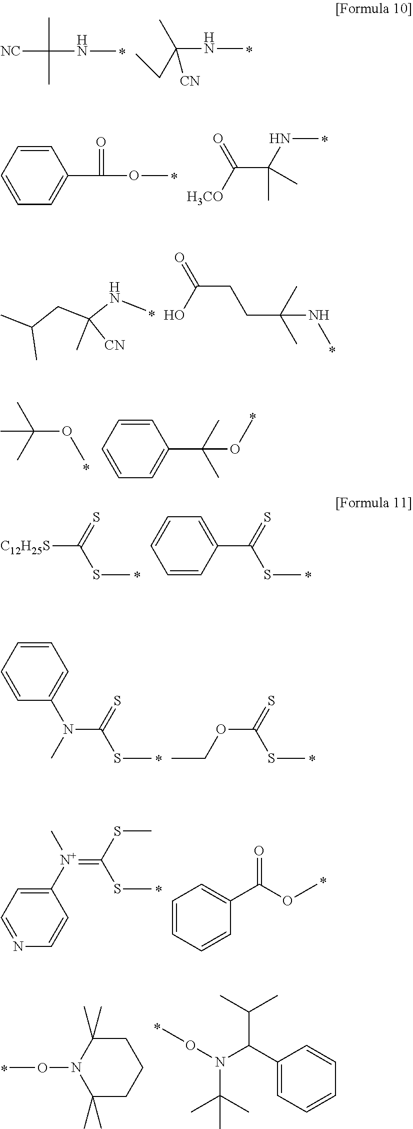

In the above structural formulae, a single asterisk (*) indicates a binding site with the main chain of the block copolymer.

### (Weight Average Molecular Weight of Copolymer)

The weight average molecular weight (Mw) of the copolymer is preferably 500 or more, more preferably 1000 or more, and even more preferably 1500 or more. The weight average molecular weight (Mw) of the copolymer is preferably 1,000,000 or less, more preferably 500,000 or less, still more preferably 300,000 or less, and even more preferably 250,000 or less. It is preferable that the weight average molecular weight (Mw) of the copolymer is within the above-described ranges from the viewpoint of the property of the residual underlayer film after coating. The weight average molecular weight (Mw) of the copolymer is a value measured in terms of polystyrene by GPC.

The ratio (Mxv/Mn) of the weight average molecular weight (Mw) and the number average molecular weight (Mn) of the copolymer is preferably 1 or more. Further, Mw/Mn is preferably 52 or less, more preferably 10 or less, still more preferably 8 or less, even more preferably 4 or less, and particularly preferably 3 or less. It is preferable to set Mw/Mn within the above-described range from the viewpoint of the property of the residual underlayer film after coating.

### (Solubility of Copolymer)

The solubility of the copolymer in at least one selected from PGMEA, PGME, THF, butyl acetate, anisole, cyclohexanone, ethyl lactate, N-methylpyrrolidone, γ-butyrolactone, and DMF is preferably 1% by mass or more, more preferably 2% by mass or more, even more preferably 3% by mass or more, and particularly preferably 4% by mass or more. The upper limit of the solubility of the copolymer in the organic solvent is not particularly limited, but can be 40% by mass, for example. The solubility refers to solubility in at least one selected from PGMEA, PGME, THF, butyl acetate, anisole, cyclohexanone, ethyl lactate, N-methylpyrrolidone, γ-butyrolactone, and DMF. The copolymer used in the present invention preferably has a solubility in any of the above organic solvents at a certain level or more.

The solubility of a copolymer can be measured by gradually adding PGMEA, PGME, THF, butyl acetate, anisole, cyclohexanone, ethyl lactate, N-methylpyrrolidone, γ-butyrolactone, or DMF to a predetermined amount of the copolymer while stirring and dissolving, and recording the amount of the organic solvent added. A magnetic stirrer or the like may be used for stirring. Then, the solubility is calculated from the following equation.

Solubility (% by mass)=Mass of copolymer/Amount of organic solvent when dissolved×100

In order to achieve the solubility of the copolymer in at least one of PGMEA, PGME, THF, butyl acetate, anisole, cyclohexanone, ethyl lactate, N-methylpyrrolidone. γ-butyrolactone, and DMF within the above range, for example, it is conceivable to determine the unit (b) to be a unit derived from an aromatic ring-containing compound. Further, in order to achieve the solubility within the above range, it is conceivable to control the content of a unit derived from a sugar derivative. Specifically, the unit (b) is determined to be a unit derived from an aromatic ring-containing compound, and the content of the unit derived from a sugar derivative (unit (a)) in the copolymer is set to a certain value or less. Accordingly, the solubility in an organic solvent can be increased more effectively.

### <Synthesis Method of Copolymer>

The copolymer can be synthesized by a known polymerization method such as living radical polymerization, living anionic polymerization, or atom transfer radical polymerization. For example, in the case of living radical polymerization, a copolymer can be obtained by reacting a monomer with a polymerization initiator such as AIBN (α,α′-azobisisobutyronitrile). In the case of living anionic polymerization, a copolymer can be obtained by reacting butyllithium with a monomer in the presence of lithium chloride. In addition, in the Examples described herein, an example of synthesis using living anionic polymerization or living radical polymerization is shown, but the present invention is not limited thereto, and the synthesis can be appropriately performed by the above-described synthesis methods or known synthesis methods.

Commercially available products may be used as a copolymer and its starting material. Examples thereof include homopolymers such as P9128D-SMMAran, P9128C-SMMAran, Poly(methyl methacrylate), P9130C-SMMAran, P7040-SMMAran, P2405-SMMA, and random polymers or block copolymers manufactured by Polymer Source, Inc. Further, these polymers can be used for carrying out synthesis as appropriate by a known synthesis method.

The polymerized portion a as described above may be obtained by synthesis, but may also be obtained by combining the steps of extraction from lignocellulose or the like derived from a woody plant or a herbaceous plant. In a case where a method of extraction from lignocellulose derived from a woody plant or a herbaceous plant is adopted for obtaining the sugar derivative portion of the polymerized portion a, the extraction method described in JP Patent Publication No. 2012-100546 A is used.

Xylan can be extracted, for example, by the method disclosed in JP Patent Publication No. 2012-180424 A.

Cellulose can be extracted, for example, by the method disclosed in JP Patent Publication No. 2014-148629 A

The polymerized portion a is preferably modified by acetylating or halogenating the OH group of the sugar portion obtained using the above extraction method before use. For example, when introducing an acetyl group, an acetylated sugar derivative portion can be obtained via a reaction with acetic anhydride.

The polymerized portion b and polymerized portion c may be formed by synthesis, or a commercially available product may be used. When polymerizing the polymerization portion b or polymerized portion c, a known synthesis method can be adopted. When using a commercially available product, for example, Amino-terminated PS (Mw=12300 Da, Mw/Mn=1.02, manufactured by Polymer Source, Inc.) can be used.

A copolymer can be synthesized with reference to Macromolecules Vol. 36, No. 6, 2003. Specifically, a compound containing the polymerized portion a and a compound containing the polymerized portion b are put in a solvent containing DMF, water, acetonitrile, and the like, and a reducing agent is added thereto. Examples of a reducing agent include NaCNBH₃. Then, the mixture is stirred at 30° C. to 100° C. for 1 day to 20 days, and a reducing agent is appropriately added if necessary. A copolymer can be obtained by adding water to obtain a precipitate and vacuum-drying the solid content.

As a method for synthesizing a copolymer, in addition to the above-described methods, a synthesis method using radical polymerization, RAFT polymerization, ATRP polymerization, click reaction, or NMP polymerization can be mentioned.

Radical polymerization is a polymerization reaction that occurs by adding an initiator to generate two free radicals by a thermal reaction or a photoreaction. A monomer (e.g., a sugar methacrylate compound in which methacrylic acid is added to the terminal position β-1 of a xylooligosaccharide-styrene monomer) and an initiator (e.g., an azo compound such as azobisbutyronitrile (AIBN)) are heated at 150° C. such that a polystyrene-polysaccharide methacrylate random copolymer can be synthesized.

RAFT polymerization is a radical-initiated polymerization reaction involving an exchange chain reaction utilizing a thiocarbonylthio group. For example, the method for synthesizing a copolymer by converting the OH group at the terminal position 1 of xylooligosaccharide into a thiocarbonylthio group, and then reacting a styrene monomer at 30° C. to 100° C. can be adopted (Material Matters vol. 0.5, No. 1, Latest Polymer Synthesis, Sigma-Aldrich Japan).

ATRP polymerization allows the terminal OH group of a sugar to be halogenated and a metal complex [(CuCl, CuCl₂, CuBr, CuBr₂, CuI, or the like)+TPMA (tris(2-pyridylmethyl)amine)], MeTREN(tris[2-(dimethylamino)ethyl]amine), or the like), a monomer (e.g., styrene monomer), and a polymerization initiator (2,2,5-trimethyl-3-(1-phenylethoxy)-4-phenyl-3-azahexane) to react so as to synthesize a sugar copolymer (e.g., sugar-styrene block copolymer).

In NMP polymerization, an alkoxyamine derivative is heated as an initiator to cause a reaction with coupling with a monomer molecule so as to generate a nitroxide. Thereafter, radicals are generated by thermal dissociation to promote the polymerization reaction. Such NMP polymerization is a type of living radical polymerization reaction. A polystyrene-polysaccharide methacrylate random copolymer can be synthesized by mixing a monomer (e.g., a sugar methacrylate compound in which methacrylic acid is added to the terminal position β-1 of a xylooligosaccharide-styrene monomer) and 2,2,6,6-tetramethylpiperidine 1-oxyl (TEMPO) as an initiator, followed by heating at 140° C.

The click reaction is a 1,3-dipolar azide/alkyne cycloaddition reaction using a sugar having a propargyl group and a Cu catalyst. In this case, a linking group having the following structure may be provided between the respective polymerized portions.

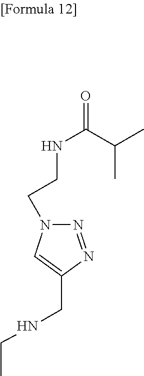 [SMILES: CCNCc1cn(CCNC(=O)C(C)C)nn1]

### <Organic Solvent>

The underlayer film-forming composition of the present invention contains an organic solvent. However, the underlayer film-forming composition may further contain an aqueous solvent such as water or various aqueous solutions, in addition to the organic solvent. Examples of the organic solvent include an alcohol solvent, an ether solvent, a ketone solvent, a sulfur-containing solvent, an amide solvent, an ester solvent, and a hydrocarbon solvent. These solvents may be used either singly or in combination of two or more types.

Examples of an alcohol solvent include: methanol, ethanol, n-propanol, i-propanol, n-butanol, i-butanol, sec-butanol, tert-butanol, n-pentanol, i-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, Furfuryl alcohol, phenol, cyclohexanol, methylcyclohexanol, 3,3,5-trimethylcyclohexanol, benzyl alcohol, and diacetone alcohol; ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, 1H,1H-trifluoroethanol, 1H,1H-pentafluoropropanol, and 6-(perfluoroethyl)hexanol.

In addition, examples of a partially etherified polyhydric alcohol solvent include ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethyleneglycol monobutyl ether, diethyleneglycol monohexyl ether, diethylene glycol dimethyl ether, diethylene glycol ethyl methyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of an ether solvent include diethyl ether, dipropyl ether, dibutyl ether, diphenyl ether, and tetrahydrofuran (THF).

Examples of a ketone solvent include acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclopentanone, cyclohexanone, cycloheptanone, cyclooctanone, methylcyclohexanone, 2,4-pentanedione, acetonylacetone, acetophenone, and furfural.

Examples of a sulfur-containing solvent include dimethyl sulfoxide.

Examples of an amide-based solvent include N,N′-dimethylimidazolidinone. N-methylformamide, N,N-dimethylformamide, N,N-diethylformamide, acetamide, N-methylacetamide, N,N-dimethylacetamide, N-methylpropionamide, and N-methylpyrrolidone.

Examples of an ester solvent include diethyl carbonate, propylene carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, propionic acid n-butyl, i-amyl propionate, methyl 3-methoxy propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of a hydrocarbon solvent include: aliphatic hydrocarbon solvents such as n-pentane, i-pentane, n-hexane, i-hexane, n-heptane, i-heptane, 2,2,4-trimethyl pentane, n-octane, i-octane, cyclohexane, and methylcyclohexane; and aromatic hydrocarbon solvents such as benzene, toluene, xylene, mesitylene, ethylbenzene, trimethylbenzene, methylethylbenzene, n-propylbenzene, i-propylbenzene, diethylbenzene, i-butylbenzene, triethylbenzene, di-i-propylbenzene, n-amyl naphthalene, and anisole.

Of these, propylene glycol monomethyl ether acetate (PGMEA), N,N-dimethylformamide (DMF), propylene glycol monomethyl ether (PGME), anisole, ethanol, methanol, acetone, methyl ethyl ketone, hexane, tetrahydrofuran (THF), dimethyl sulfoxide (DMSO), 1H,1H-trifluoroethanol, 1H,1H-pentafluoropropanol, 6-(perfluoroethyl)hexanol, ethyl acetate, propyl acetate, butyl acetate, cyclohexanone, furfural, N-methylpyrrolidone, and γ-butyrolactone are more preferable, PGMEA, PGME, THF, butyl acetate, anisole, cyclohexanone, N-methylpyrrolidone. γ-butyrolactone, or DMF is more preferable, and PGMEA is even more preferable. These solvents may be used either singly or in combination of two or more types.

The content of the organic solvent is preferably 10% by mass or more, more preferably 20% by mass or more, and even more preferably 30% by mass or more with respect to the total mass of the underlayer film-forming composition. Moreover, the content of the organic solvent is preferably 99.9% by mass or less, and more preferably 99% by mass or less. By setting the content of the organic solvent within the above range, the coatability of the underlayer film-forming composition can be improved.

### <Optional Components>

The underlayer film-forming composition of the present invention may contain optional components as described below.

### <<Sugar Derivative>>

The underlayer film-forming composition of the present invention may further contain a sugar derivative, in addition to the copolymer. Examples of the sugar derivative include a xylose derivative, a xylooligosaccharide derivative, a glucose derivative, a cellulose derivative, and a hemicellulose derivative. Among them, at least one selected from a xylooligosaccharide derivative and a glucose derivative is more preferable.

The underlayer film-forming composition of the present invention may further contain a monomer having a structure derived from a sugar derivative, in addition to the copolymer. The monomer containing a structure derived from a sugar derivative is preferably one represented by the formula (1′) or (2′) described later. Note that, in the formulae (1′) and (2′), the structure of a sugar derivative is described as a cyclic structure, but the structure of a sugar derivative is not limited to a cyclic structure and may be an open ring structure (chain structure) called aldose or ketose.

The structure represented by the formula (1′) will be described below.

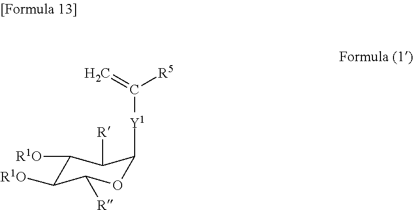

In the formula (1′), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different.

R′ represents a hydrogen atom, —OR¹¹, or —NR¹²₂.

R″ represents a hydrogen atom, —OR¹¹, —COOR¹³, or —CH₂OR¹³. Here, R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

R⁵ represents a hydrogen atom or an alkyl group.

Each Y¹ independently represent a single bond or a linking group;

In the formula (V), specific aspects and preferable aspects of R¹, R′, R″, R⁵, and Y¹ are the same as those of R¹, R′, R″, R⁵, and Y¹ in the formula (1), respectively. In order to effectively carry out polymerization, at least one R¹ is preferably an acyl group, an aryl group, or a trimethylsilyl group, and more preferably an acyl group which is especially-COCH₃ or —COC₂H₅.

The structure represented by the formula (2′) will be described below.

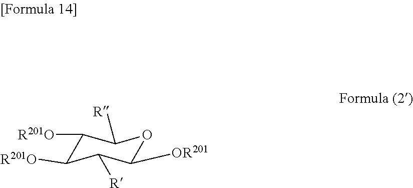

In the formula (2), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different:

R′ represents a hydrogen atom, —OR¹¹, or —NR¹²₂.

R″ represents a hydrogen atom, —OR¹¹, —COOR¹³, or —CH₂OR¹³. Here, R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

In the formula (2), preferable ranges of R²⁰¹, R′, and R″ are the same as the preferable ranges of R¹, R′, and R″ in the formula (1). In order to effectively carry out polymerization, at least one R²⁰¹ is preferably an acyl group, an aryl group, or a trimethylsilyl group, and more preferably an acyl group which is especially —COCH₃ or —COC₂H₅.

The present invention may also relate to a monomer for an underlayer film-forming composition. Specifically, the present invention may relate to a monomer containing a structure derived from a sugar derivative used as an underlayer film-forming composition. Alternatively, it may relate to a monomer for an underlayer film-forming composition having a structure represented by the formula (V) or (2′).

### <<Crosslinkable Compound>>

The underlayer film-forming composition of the present invention may further contain a crosslinkable compound. An underlayer film formed by a crosslinking reaction becomes strong, and etching workability can be more effectively enhanced.

The crosslinkable compound is not particularly limited, but a crosslinkable compound having at least two crosslinkable substituents is preferably used. A compound having two or more, for example, 2 to 6, crosslinkable substituents of at least one type selected from an isocyanate group, an epoxy group, a (meth)acryloyl group, a hydroxy methylamino group, and an alkoxymethylamino group can be used as the crosslinkable compound.

Examples of the crosslinkable compound include a nitrogen-containing compound having two or more, for example, 2 to 6, nitrogen atoms substituted with a hydroxymethyl group, an alkoxymethyl group, an epoxy group, or a (meth)acryloyl group. Above all, the crosslinkable compound is preferably a nitrogen-containing compound having a nitrogen atom substituted with a group such as a hydroxymethyl group, a methoxymethyl group, an ethoxymethyl group, a butoxymethyl group, or a hexyloxymethyl group. Specific examples thereof include nitrogen-containing compounds such as hexamethoxy methyl melamine, tetramethoxymethyl benzoguanamine, 1,3,4,6-tetrakis(butoxymethyl)glycoluril, 1,3,4,6-tetrakis(hydroxymethyl)glycoluril, 1,3-bis(hydroxy methyl)urea, 1,1,3,3-tetrakis(butoxymethyl)urea, 1,1,3,3-tetrakis(methoxymethyl)urea, 1,3-bis(hydroxymethyl)-4,5-dihydroxy-2-imidazolinone, 1,3-bis(methoxymethyl)-4,5-dimethoxy-2-imidazolinone, dicyclohexylcarbodiimide, diisopropylcarbodiimide, di-tert-butylcarbodiimide, and piperazine.

In addition, as the crosslinkable compound, commercially available compounds such as methoxymethyl-type melamine compounds (trade name: CYMELS® 300, CYMEL® 301, CYMEL® 303, and CYMEL® 350), butoxymethyl-type melamine compounds (trade name: MYCOAT® 506 and MYCOAT® 508), glycoluril compounds (trade name: CYMEL® 1170 and POWDERLINK® 1174), methylated urea resins (trade name: UFR65), and butylated urea resins (trade name. UFR300, U-VAN10S60, U-VAN10R, and U-VAN11HV) manufactured by Mitsui Cytec Ltd., urea-formaldehyde resins (trade name: BECKAMINE J-300S, BECKAMINE P-955, and BECKAMINE N) manufactured by Dainippon Ink and Chemicals Inc., (meth)acrylate monomers (trade name: SR209 and SR272) and epoxy acrylate oligomer (CN110NS) manufactured by ARKEMA K.K., and neopentyl glycol diglycidyl ether manufactured by Tokyo Chemical Industry Co., Ltd. can be used. Moreover, as the crosslinkable compound, a polymer produced using an acrylamide compound or a methacrylamide compound substituted with a hydroxymethyl group or an alkoxymethyl group such as N-hydroxymethyl acrylamide, N-methoxymethyl methacrylamide. N-ethoxymethyl acrylamide, or N-butoxymethyl methacrylamide can be used.

Only one type of compound may be used as a crosslinkable compound. Alternatively, two or more types of crosslinkable compounds may be used in combination.

These crosslinkable compounds can cause a crosslinking reaction by self-condensation. They may also cause a crosslinking reaction with the constitutional units contained in a polymer.

### <<Catalyst>>

An acid compound such as p-toluenesulfonic acid, trifluoromethanesulfonic acid, pyridinium-p-toluenesulfonic acid, salicylic acid, sulfosalicylic acid, citric acid, benzoic acid, ammonium dodecylbenzenesulfonate, or hydroxybenzoic acid can be added as a catalyst for promoting the crosslinking reaction to the underlayer film-forming composition. Examples of the acid compound may include aromatic sulfonic acid compounds such as p-toluenesulfonic acid, pyridinium-p-toluenesulfonic acid, sulfosalicylic acid, 4-chlorobenzenesulfonic acid, 4-hydroxybenzenesulfonic acid, benzenedisulfonic acid, 1-naphthalenesulfonic acid, and pyridinium-1-naphthalenesulfonic acid. In addition, an acid generator such as 2,4,4,6-tetrabromocyclohexadienone, benzoin tosylate, 2-nitrobenzyl tosylate, bis(4-tert-butylphenyl)iodonium trifluoromethanesulfonate, triphenylsulfonium trifluoromethanesulfonate, phenyl-bis(trichloromethyl)-s-triazine, benzoin tosylate, N-hydroxysuccinimide trifluoromethanesulfonate, bis-(t-butylsulfonyl)diazomethane, or cyclohexylsulfonyldiazomethane can be added.

### <<Light Reflection Preventing Agent>>

The underlayer film-forming composition of the present invention may further contain a light antireflection agent. As a light antireflection agent, for example, a light-absorbing compound can be mentioned. Examples of a light-absorbing compound may include those having high light-absorbing ability in the photosensitive characteristic wavelength region of a photosensitive component in a photoresist provided on the underlayer film such as a benzophenone compound, a benzotriazole compound, an azo compound, a naphthalene compound, an anthracene compound, an anthraquinone compound, and a triazine compound. Examples of a polymer may include poly ester, polyimide, polystyrene, novolac resin, poly acetal, and acrylic polymer. Examples of a polymer having a light-absorbing group linked by a chemical bond include a polymer having a light-absorbing aromatic ring structure such as an anthracene ring, a naphthalene ring, a benzene ring, a quinoline ring, a quinoxaline ring, or a thiazole ring.

### <<Other Components>>

The underlayer film-forming composition may further contain an ionic liquid, a surfactant, and the like. By incorporating an ionic liquid in the underlayer film-forming composition, the compatibility between a copolymer and an organic solvent can be increased.

By including a surfactant in the underlayer film-forming composition, the coatability of the underlayer film-forming composition on a substrate can be improved. Further, when forming a pattern using the underlayer film-forming composition, it is possible to improve coatability of a resist composition or the like applied subsequently to the underlayer film-forming composition. Examples of a preferable surfactant include a nonionic surfactant, a fluorine surfactant, and a silicone surfactant.

In addition, any known material such as a rheology modifier and an adhesion aid may be included in the underlayer film-forming composition.

The content of the optional component as described above is preferably 10% by mass or less, and more preferably 5% by mass or less with respect to the total mass of the underlayer film-forming composition.

### (Underlayer Film)

The present invention may relate to an underlayer film formed from the above-described underlayer film-forming composition. The underlayer film is a layer provided on a substrate such as a silicon wafer. An underlayer film processed into a pattern shape is also referred herein to as a “protective film,” but such a protective film is also included in the underlayer film. That is to say, the underlayer film includes a layered film before patterning and an intermittent film after patterning.

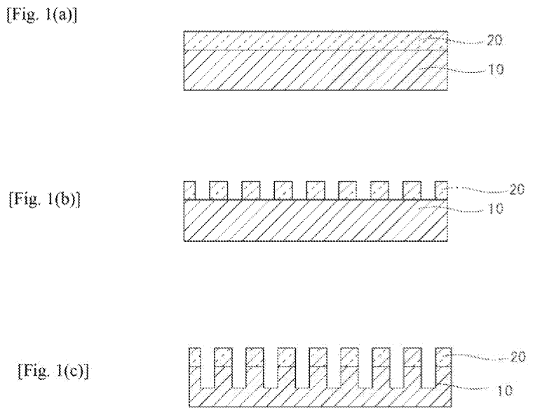

FIG. 1(a) illustrates a laminated body in which an underlayer film 20 is formed on a substrate 10. Although not shown, the underlayer film is preferably a layer provided in an underlayer of a resist film, for example. That is to say, the underlayer film is preferably a layer provided between the substrate and the resist film. The underlayer film can also function as a layer for preventing the interaction between the substrate and the resist film, a layer for preventing a material used for the resist film or a substance generated during exposure to the resist film form adversely affecting the substrate, a layer for preventing diffusion of a substance generated from the substrate during heating and baking into the resist film, a barrier layer for reducing poisoning effects of the resist film by a semiconductor substrate dielectric layer, or the like. The underlayer film also functions as a flattening material for flattening the substrate surface.

As shown in FIG. 1(b), at least a part of the underlayer film 20 is removed so as to have a pattern shape to be formed on the substrate 10. For example, by laminating a resist film on the underlayer film 20 and performing exposure and development treatment, a pattern shape as shown in FIG. 1(b) can be formed. Then, a pattern as shown in FIG. 1(c) is formed on the substrate 10 by performing reactive ion etching with inductively coupled plasma or the like on the exposed substrate 10 using chlorine gas, boron trichloride, tetrafluoromethane gas, trifluoromethane gas, hexafluoroethane gas, octafluoropropane gas, sulfur hexafluoride gas, argon gas, oxygen gas, or helium gas.

It is also possible to form a self-assembled film and a resist film from the underlayer film-forming composition of the present invention. In a case where the underlayer film-forming composition contains a block copolymer, a pattern can be formed by forming a film having a phase-separated structure due to self-assembly (self-assembled film) by applying a block copolymer on a substrate and performing annealing or the like, and removing a part of the phase in the self-assembled film. Further, in a case where a resist film is formed from the underlayer film-forming composition, a resist film formed form the underlayer film-forming composition is irradiated with far-ultraviolet light having a short wavelength through a mask on which a circuit pattern is drawn, and the pattern is transferred by altering portions of the resist film exposed to the light (exposure). Then, a pattern can be formed by melting the exposed portions with a developer.

The film thickness of the underlayer film can be appropriately adjusted depending on the application, but is preferably 1 nm to 20000 nm, more preferably 1 nm to 10000 nm, even more preferably 1 nm to 5000 nm, and particularly preferably 1 nm to 3000 nm.

The underlayer film is preferably a film into which a metal has been introduced, and as a result, it is preferable that the underlayer film contains a metal. The metal content in the underlayer film is preferably 5 at % or more, more preferably 8 at % or more, even more preferably 10 at % or more, and particularly preferably 15 at % or more. The metal content can be calculated, for example, by the following method. First, the underlayer film is placed in an atomic layer deposition apparatus (ALD), and Al(CH₃)₃ gas is introduced therein at 95° C., and then steam is introduced. By repeating this operation three times, Al is introduced into the underlayer film EDX analysis (energy dispersive X-ray analysis) is performed on the underlayer film after introduction of Al by using an electron microscope JSM7800F (manufactured by JEOL Ltd.) to calculate an Al component ratio (Al content), which is used as a metal content.

### (Pattern-Forming Method)

The present invention also relates to a pattern-forming method using the underlayer film-forming composition described above. The pattern-forming method of the present invention includes a step of forming an underlayer film with the underlayer film-forming composition described above.

The pattern-forming method preferably includes a step of introducing a metal into the underlayer film-forming composition and/or the underlayer film. Above all, the pattern-forming method more preferably includes a step of introducing a metal into the underlayer film.

The pattern-forming method preferably includes a lithographic process prior to the step of introducing a metal. The lithography process preferably includes a step of forming a resist film on the underlayer film and a step of removing a part of the resist film and the underlayer film to form a pattern.

A step of forming a guide pattern on a substrate may be further included between the step of forming an underlayer film and the step of forming a resist film. The step of forming a guide pattern on a substrate may be provided before the step of applying the underlayer film-forming composition. The step of forming a guide pattern is a step of forming a prepattern on the underlayer film formed in the step of applying the underlayer film-forming composition.

The pattern-forming method preferably includes a step of processing a semiconductor substrate using the above-described pattern as a protective film. Such a step is called an etching step.

### <Step of Forming Underlayer Film>

The pattern-forming method of the present invention preferably includes a step of forming an underlayer film. The step of forming an underlayer film is a step of applying an underlayer film-forming composition on a substrate to form an underlayer film.

Examples of a substrate include substrates of glass, silicon, SiO₂, SiN, GaN, and AlN. Further, a substrate made of an organic material such as PET, PE, PEO, PS, cycloolefin polymer, poly lactic acid, or cellulose nanofiber may be used.

The substrate and the underlayer film are preferably laminated so that the layers adjacent to each other in this order are in direct contact with each other, but other layers may be provided between the respective layers. For example, an anchor layer may be provided between the substrate and the underlayer film. The anchor layer is a layer that controls wettability of the substrate and is a layer that enhances adhesiveness between the substrate and the underlayer film. Further, a plurality of layers made of different materials may be sandwiched between the substrate and the underlayer film. Examples of these materials may include, but are not particularly limited to, inorganic materials such as SiO₂, SiN, Al₂O₃, AlN, GaN, GaAs, W, SOC, SOG, Cr, Mo, MoSi, Ta, Ni, Ru, TaBN, and Ag and organic materials such as commercially available adhesives.

The method for applying the underlayer film-forming composition is not particularly limited, but for example, the underlayer film-forming composition can be applied on the substrate by a known method such as spin coating. After applying the underlayer film-forming composition, the underlayer film-forming composition may be cured by exposure and/or heating to form the underlayer film. Examples of radioactive rays used for such exposure include visible light, ultraviolet light, far ultraviolet light, X-ray, electron beam, γ-ray, molecular beam, and ion beam. The temperature for heating the coating film is not particularly limited, but is preferably 90° C. to 550° C.

It is preferable to provide a step of cleaning the substrate before applying the underlayer film-forming composition to the substrate. By cleaning the substrate surface, coatability of the underlayer film-forming composition is improved. As a method of cleaning treatment, a conventionally known method can be used, and examples thereof include oxygen plasma treatment, ozone oxidation treatment, acid-alkali treatment, and chemical modification treatment.

After forming the underlayer film, it is preferable that heat treatment (baking) is performed to form a layer of the underlayer film from the underlayer film-forming composition. In the present invention, the heat treatment is preferably a heat treatment in the air at a relatively low temperature.

The conditions for heat treatment are preferably selected appropriately within the ranges of a heat treatment temperature of 60° C. to 350° C. and a heat treatment time of 0.3 to 60 minutes. Above all, the heat treatment temperature is more preferably 130° C. to 250° C., and the heat treatment time is more preferably 0.5 to 30 minutes and even more preferably 0.5 to 5 minutes.

After forming the underlayer film, the underlayer film may be rinsed with a rinse liquid such as a solvent, if necessary. Since the uncrosslinked portion and the like in the underlayer film are removed by rinse treatment, the film forming property of a film such as a resist formed on the underlayer film can be improved.

In addition, the rinse liquid may be any rinse liquid as long as it can dissolve the uncrosslinked portion, a solvent such as propylene glycol monomethyl ether acetate (PGMEA), propylene glycol monomethyl ether (PGME), ethyl lactate (EL), or cyclohexanone, a commercially available thinner solution, or the like can be used.

In addition, post-baking may be performed after washing in order to volatilize the rinse liquid. The temperature condition of this post-baking is preferably 80° C. to 300° C., and the baking time is preferably 30 seconds to 600 seconds.

Since the underlayer film formed from the underlayer film-forming composition of the present invention has a property of absorbing UV rays, it can also function as a light antireflection film. A light antireflection film may be further formed separately from the underlayer film as described later.

In a case where the underlayer film is used as a light antireflection film in a lithography process using a KrF excimer laser (wavelength: 248 nm), the underlayer film-forming composition preferably contains a component having an anthracene ring or a naphthalene ring. In a case where the underlayer film is used as a light antireflection film in a lithography process using an ArF excimer laser (wavelength: 193 nm), the underlayer film-forming composition preferably contains a compound having a benzene ring. In addition, in a case where the underlayer film is used as a light antireflection film in a lithography process using an F2 excimer laser (wavelength: 157 nm), the underlayer film-forming composition preferably contains a compound having a bromine atom or an iodine atom.

Further, the underlayer film can also function as a layer for preventing the interaction between the substrate and the photoresist, a layer for preventing a material used for the photoresist or a substance generated during exposure to the photoresist form adversely affecting the substrate, a layer for preventing diffusion of a substance generated from the substrate during heating and baking into the photoresist, a barrier layer for reducing poisoning effects of the photoresist by a semiconductor substrate dielectric layer, or the like. The underlayer film formed from the underlayer film-forming composition also functions as a flattening material for flattening the substrate surface.

### <Step of Forming Light Antireflection Film>

In a case where the pattern-forming method is used in a semiconductor manufacturing method, a step of forming an organic or inorganic light antireflection film may be provided before and after the formation of the underlayer film on the substrate. In this case, a light antireflection film may be further provided in addition to the underlayer film.

The composition for a light antireflection film used for forming the light antireflection film is not particularly limited, and can be arbitrarily selected and used from those commonly used in the lithography process. Further, a light antireflection film can be formed by a commonly used method, for example, coating with a spinner or a coater and baking. Examples of the composition for a light antireflection film include a composition containing a light-absorbing compound and a polymer as main components, a composition containing a polymer having a light-absorbing group linked by a chemical bond and a cross-linking agent as main components, a composition containing a light-absorbing compound and a cross-linking agent as main components, and a composition containing a light-absorbing polymer crosslinking agent as main components. These compositions for a light antireflection film also contain an acid component, an acid generator component, a rheology modifier, and the like, if necessary. As a light-absorbing compound, those having high light-absorbing ability in the photosensitive characteristic wavelength region of a photosensitive component in a photoresist provided on the light antireflection film can be used. Examples thereof include a benzophenone compound, a benzotriazole compound, an azo compound, a naphthalene compound, an anthracene compound, an anthraquinone compound, and a triazine compound. Examples of a polymer may include polyester, polyimide, polystyrene, novolac resin, poly acetal, and acrylic poly mer. Examples of a polymer having a light-absorbing group linked by a chemical bond include a polymer having a light-absorbing aromatic ring structure such as an anthracene ring, a naphthalene ring, a benzene ring, a quinoline ring, a quinoxaline ring, or a thiazole ring.

A substrate to which the underlayer film-forming composition of the present invention is applied may have an inorganic light antireflection film formed by a CVD method or the like on the surface thereof, and the underlayer film may be formed thereon.

### <Step of Forming Resist Film>

The step of forming a resist film is preferably a step of forming a photoresist layer The formation of a photoresist layer is not particularly limited, but a well-known method can be adopted. For example, a photoresist layer can be formed by applying a photoresist composition solution onto an underlayer film, followed by baking.

A photoresist that is applied and formed on the underlayer film is not particularly limited as long as it is sensitive to the light used for exposure. Further, both a negative type photoresist and a positive type photoresist can be used. Examples thereof include, a positive photoresist comprising a novolac resin and 1,2-naphthoquinonediazide sulfonate; a chemically amplified photoresist comprising a binder having a group that decomposes with an acid to increase the alkali dissolution rate and a photoacid generator; a chemically amplified photoresist composed of a low-molecular-weight compound that decomposes with acid to increase the alkali dissolution rate of a photoresist, an alkali-soluble binder, and a photoacid generator; and a chemically amplified photoresist comprising a binder having a group that decomposes with an acid to increase the alkali dissolution rate, a low molecular weight compound that decomposes with an acid to increase the alkali dissolution rate of a photoresist, and a photoacid generator. For example, APEX-E (trade name) manufactured by Shipley Company, Inc., PAR710 (trade name) manufactured by Sumitomo Chemical Industry Company Limited, and SEPR430 (trade name) manufactured by Shin-Etsu Chemical Co., Ltd. can be mentioned. Note that the underlayer film-forming composition of the present invention can also be used as a resist film-forming composition.

The step of forming a resist film preferably includes a step of performing exposure through a predetermined mask. KrF excimer laser (wavelength: 248 nm), ArF excimer laser (wavelength: 193 nm), F2 excimer laser (wavelength: 157 nm), extreme ultraviolet light (EUV) (wavelength: 13 nm), and the like can be used for exposure. After exposure, post-exposure bake can be performed if necessary. The post-exposure bake is preferably performed under conditions of a heating temperature of 70° C. to 150° C. and a heating time of 0.3 to 10 minutes.

The step of forming a resist film preferably includes a step of performing development with a developer. Thus, for example, in a case where a positive photoresist is used, the photoresist of the exposed portion is removed and a photoresist pattern is formed. Examples of a developer may include: aqueous solutions of alkali metal hydroxide such as potassium hydroxide and sodium hydroxide; aqueous solutions of quaternary ammonium hydroxide such as tetramethylammonium hydroxide, tetraethylammonium hydroxide, and choline; and alkaline aqueous solutions such as amine solutions of ethanolamine, propylamine, and ethylenediamine. Further, a surfactant or the like can be added to these developers. The development conditions are appropriately selected from a temperature of 5° C. to 50° C. and a time of 10 to 300 seconds.

A resist film may be formed using nanoimprint lithography in addition to the above-described photolithography. In the case of nanoimprint lithography, a resist film can be formed by applying a photocurable nanoimprint resist, pressing a pattern-formed mold against the resist, and irradiating with light such as UV. In addition, a resist film may be a self-assembled film

### <Step of Forming Pattern of Underlayer Film>

In the pattern-forming method, it is preferable that a part of the underlayer film is removed using the pattern of the resist film formed in the step of forming a resist film as a protective film. Such a step is called a step of forming a pattern of an underlayer film.

As a method for removing a part of an underlayer film, known methods including reactive ion etching (RIE) such as chemical dry etching or chemical wet etching (wet development) and physical etching such as sputter etching or ion beam etching can be mentioned. It is preferable to remove an underlayer film by, for example, dry etching using gases of tetrafluoromethane, perfluorocyclobutane (C₄F₈), perfluoropropane (C₃F₈), perfluoroethane (C₂F₆), boron trichloride, methane trifluoride, trifluoromethane, carbon monoxide, argon, oxygen, nitrogen, chlorine, helium, sulfur hexafluoride, difluoromethane, nitrogen trifluoride, chlorine trifluoride, and the like.

Further, a chemical wet etching step can be adopted as a step of removing a part of an underlayer film. Examples of a wet etching technique include a method of treatment by a reaction with acetic acid, a method of treatment by a reaction with a mixed solution of alcohol and w ater such as ethanol or i-propanol, and a method of treatment with acetic acid or alcohol after irradiation with UV light or EB light.

### <Step of Introducing Metal>

It is preferable that the pattern-forming method further includes a step of introducing a metal into an underlayer film, such as a sequential infiltration synthesis (SIS) method. Examples of a metal to be introduced include Li, Be, B, Na, Mg, Al, Si, K, Ca, Sc, Ti, V, Cr, Mn, Fe, Co, Ni, Cu, Zn, Ga, Ge, As, Rb, Sr, Y, Zr, Nb, Mo, Ru, Pd, Ag, Cd, In, Sn, Sb, Te, Cs, Ba, La, Hf, Ta, W, Re, Os, Ir, Pt, Au, Hg, Tl, Pb, Bi, Po, Ce, Pr, Nd, Pm, Sm, Eu, Gd, Tb, Dv, Ho, Er, Tm, Yb, and Lu. Such a process can be carried out by, for example, the method described in Journal of Photopolymer Science and Technology Volume 29, Number 5 (2016) 653-657. Further, in the step of introducing a metal, a method for using a metal complex gas, a method for applying a solution containing a metal, or an ion injection method can be adopted.

The step of introducing a metal is preferably provided after forming an underlayer film. For example, it is preferable to provide a step of forming a resist film, a step of forming a pattern of an underlayer film, a step of introducing a metal, and an etching step in that order after forming an underlayer film. However, the step of introducing a metal may be provided before the step of forming an underlayer film. That is to say, the target for introducing a metal is not limited to an underlayer film, and may be an underlayer film-forming composition.

### <Etching Step>

In the pattern-forming method, it is preferable that a semiconductor substrate is processed using the pattern of the resist film formed in the above-described step of forming a resist film as a protective film. Such a step is called an etching step.

As a method for processing a semiconductor substrate in the etching step, known methods including reactive ion etching (RIE) such as chemical dry etching or chemical wet etching (wet development) and physical etching such as sputter etching or ion beam etching can be mentioned. It is preferable to process a semiconductor substrate by, for example, dry etching using gases of tetrafluoromethane, perfluorocyclobutane (C₄F₈), perfluoropropane (C₃F₈), trifluoromethane, carbon monoxide, argon, helium, oxygen, nitrogen, chlorine, sulfur hexafluoride, difluoromethane, nitrogen trifluoride, chlorine trifluoride, and the like.

Further, a chemical wet etching step can be adopted in the etching step. Examples of a wet etching technique include a method comprising treatment by a reaction with acetic acid, a method comprising treatment by a reaction with a mixed solution of alcohol and water such as ethanol or i-propanol, and a method comprising treatment with acetic acid or alcohol after irradiation with UV light or EB light.

### <Use of Pattern>

The pattern formed as described above is also preferably used as a guide for patterning using a self-assembled pattern-forming material (DSA: directed self-assembly lithography). It is also preferably used as a mold for nanoimprint lithography.

Further, the pattern-forming method can be applied to various manufacturing methods. For example, the pattern-forming method may be used in semiconductor manufacturing steps. An example of a semiconductor manufacturing method preferably includes a step of forming a pattern on a semiconductor substrate by the pattern-forming method.

### EXAMPLES

The characteristics of the present invention are further specifically described with reference to Examples and Comparative Examples given hereinunder. In the following Examples, the material used, its amount and ratio, the details of the treatment and the treatment process may be suitably modified or changed not overstepping the spirit and the scope of the invention. Accordingly, the invention should not be restrictively interpreted by the specific examples mentioned below.

Note that l, m, n, and r in Examples of the copolymer each indicate the number of constitutional units contained in the copolymer.

### [Preparation of Sugars]

Xylooligosaccharides and xylose were obtained by extracting from wood pulp with reference to JP Patent Publication No. 2012-100546 A.

D-(+) glucose used herein was manufactured by Wako Pure Chemical Industries, Ltd.

### [Synthesis of Random Copolymer]

### <Synthesis of Copolymer 1>

### (Synthesis of Acetyl Sugar Methacrylate 1)

10 g of xylooligosaccharide (average degree of polymerization: 3) was added to a mixed solution of 120 g of acetic anhydride and 160 g of acetic acid, and the mixture was stirred at 30° C. for 2 hours. Cold water in an amount about 5 times the solution was added slowly with stirring, and the mixture was stirred for 2 hours and then left standing overnight. 10 g of precipitated crystals were added to a solution prepared by adding 0.6 g of ethylenediamine and 0.7 g of acetic acid to 200 mL of THF in a flask and bringing the temperature to 0° C., and the mixture was stirred for 4 hours. The resulting solution was poured into 500 mL of cold w ater and extracted twice with dichloromethane. 10 g of this extract, 150 mL of dichloromethane, and 2.4 g of triethylamine w ere placed in a flask and cooled to −30° C. 1.4 g of methacryloyl chloride was added, and the mixture was stirred for 2 hours. The resulting mixture was poured into 150 mL of cold water, extracted twice with dichloromethane, and the solvent was concentrated to obtain 8.1 g of acetyl sugar methacrylate 1. The structure of the obtained acetyl sugar methacrylate 1 is as follows.

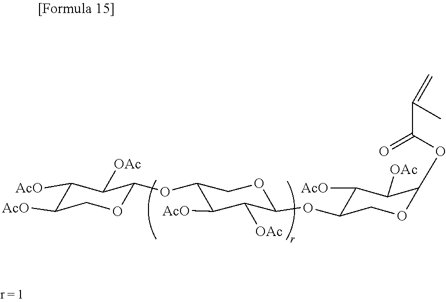

### (Synthesis of Random Copolymer of Styrene-Methyl Methacrylate-Acetyl Sugar Methacrylate 1)

500 mL of tetrahydrofuran and 92 g of a THF solution (manufactured by Tokyo Chemical Industry Co., Ltd.) containing 2.6% by mass of lithium chloride were added to a flask and cooled to −78° C. under an argon atmosphere. 13 g of a hexane solution (manufactured by Tokyo Chemical Industry Co., Ltd.) containing 15.4% by mass of n-butyllithium was added thereto, and the mixture was stirred for 5 minutes and then dehydrated and degassed. Then, a mixture of acetyl sugar methacrylate 1 (30 g), 20 g of styrene (manufactured by Tokyo Chemical Industry Co., Ltd), and 20 g of methyl methacrylate was added and stirred for 30 minutes. Then, the reaction was terminated by adding 14 g of methanol, thereby synthesizing copolymer 1. The structures of the constitutional units (a), (b), and (c) contained in copolymer 1 are as follows.

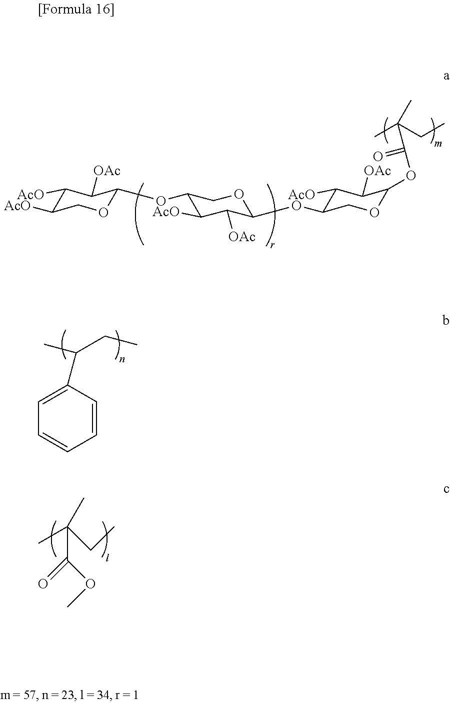

### <Synthesis of Copolymer 2>

(Synthesis of Random Copolymer of Styrene-Butyl Acrylate-Acetyl Sugar Methacrylate 1) Copolymer 2 was synthesized in the same manner as in the synthesis of random

copolymer of styrene-methyl methacrylate-acetyl sugar methacrylate 1 except that butyl acrylate was used instead of methyl methacrylate in the synthesis of random copolymer of styrene-methyl methacrylate-acetyl sugar methacrylate 1. The structures of the constitutional units (a), (b), and (c) contained in copolymer 2 are as follows.

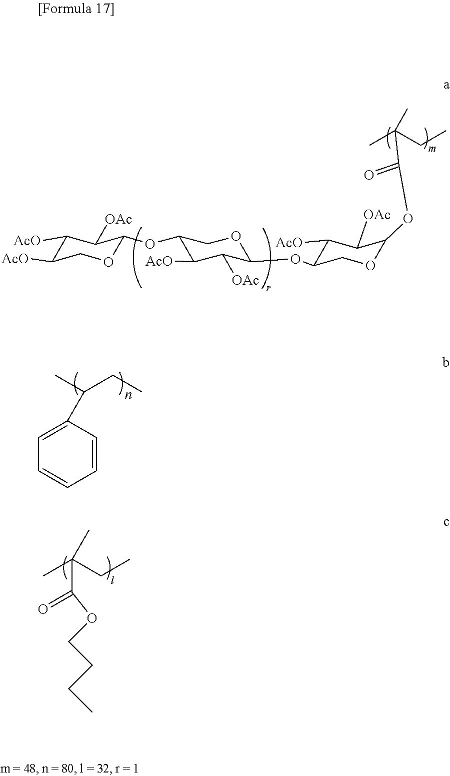

### <Synthesis of Copolymer 3>

### (Synthesis of Random Copolymer of Styrene-Methyl Acrylate-Acetyl Sugar Methacrylate 1)

Copolymer 3 was synthesized in the same manner as in the synthesis of random copolymer of styrene-methyl methacrylate-acetyl sugar methacrylate 1 except that methyl acrylate was used instead of methyl methacrylate in the synthesis of random copolymer of styrene-methyl methacrylate-acetyl sugar methacrylate 1. The structures of the constitutional units (a), (b), and (c) contained in copolymer 3 are as follows.

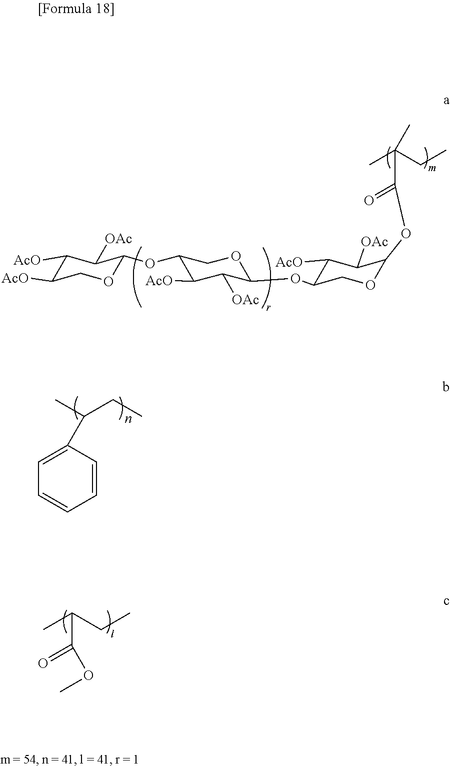

### <Synthesis of Copolymer 4>

### (Synthesis of Random Copolymer of Naphthalene-Methyl Acrylate-Acetyl Sugar Methacrylate 1)

Copolymer 4 was synthesized in the same manner as in the synthesis of random copolymer of styrene-methyl acrylate-acetyl sugar methacrylate 1 except that 1-vinylnaphthalene (manufactured by Tokyo Chemical Industry Co., Ltd.) was used instead of styrene in the synthesis of random copolymer of styrene-methyl acrylate-acetyl sugar methacrylate 1. The structures of the constitutional units (a), (b), and (c) contained in copolymer 4 are as follows.

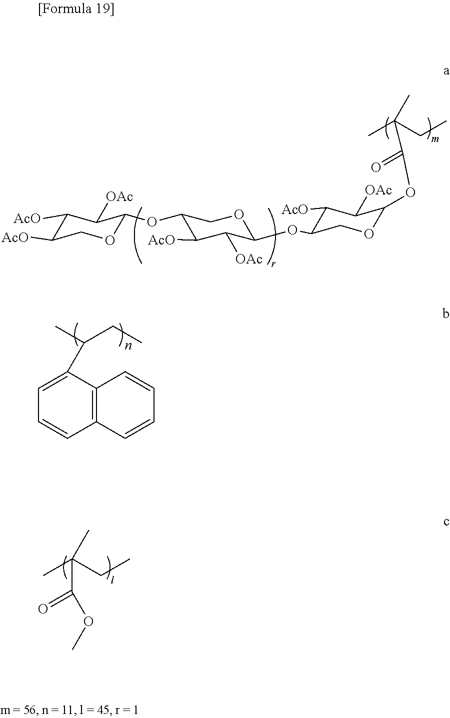

### <Synthesis of Copolymer 5>

### (Synthesis of Random Copolymer of Styrene-Hydroxyethyl Methacrylate-Acetyl Sugar Methacrylate 1)

Copolymer 5 was synthesized in the same manner as in the synthesis of random copolymer of styrene-methyl acrylate-acetyl sugar methacrylate 1 except that hydroxyethyl methacrylate (manufactured by Tokyo Chemical Industry Co., Ltd.) was used instead of methyl acrylate in the synthesis of random copolymer of styrene-methyl acrylate-acetyl sugar methacrylate 1. The structures of the constitutional units (a), (b), and (c) contained in copolymer 5 are as follows.

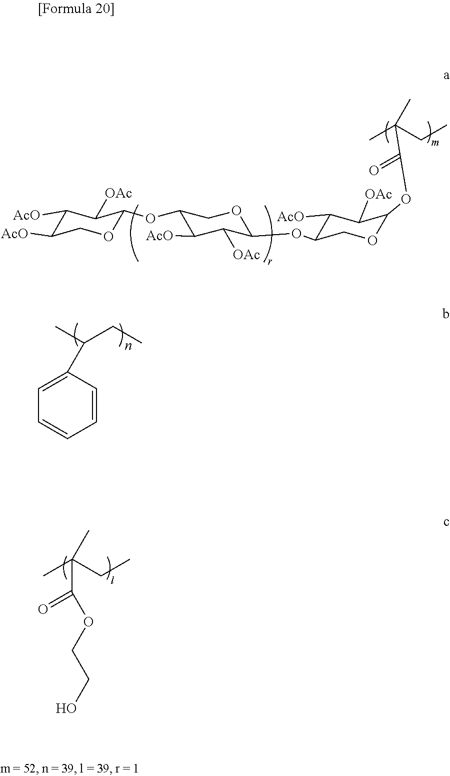

### <Synthesis of Copolymer 6>

### (Synthesis of Random Copolymer of Styrene-Acrylic Acid-Acetyl Sugar Methacrylate 1)

Copolymer 6 was synthesized in the same manner as in the synthesis of random copolymer of styrene-methyl methacrylate-acetyl sugar methacrylate 1 except that acrylic acid (manufactured by Tokyo Chemical Industry Co., Ltd.) was used instead of methyl methacrylate in the synthesis of random copolymer of styrene-methyl methacrylate-acetyl sugar methacrylate 1. The structures of the constitutional units (a), (b), and (c) contained in copolymer 6 are as follows.

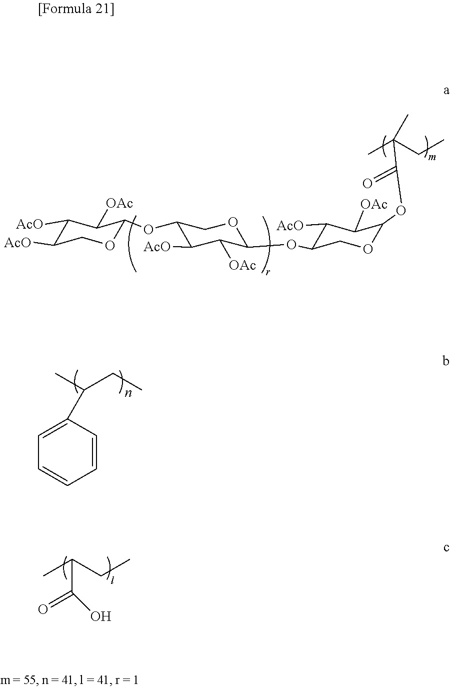

### <Synthesis of Copolymer 7>

### (Synthesis of Acetyl Sugar Methacrylate 2)

Acetyl sugar methacrylate 2 was synthesized in the same manner as in the synthesis of acetyl sugar methacrylate 1 except that xylose was used instead of xylooligosaccharide having an average degree of polymerization of 3 in the synthesis of acetyl sugar methacrylate 1. The structure of the obtained acetyl sugar methacrylate 2 is as follows.

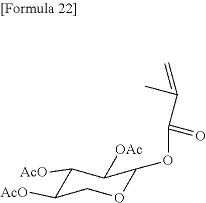 [SMILES: C=C(C)C(=O)OC1OCC(OC(C)=O)C(OC(C)=O)C1OC(C)=O]

### (Synthesis of Random Copolymer of Styrene-Methacrylate-Acetyl Sugar Methacrylate 2)

Copolymer 7 was synthesized in the same manner as in the synthesis of random copolymer of styrene-methyl methacrylate-acetyl sugar methacrylate 1 except that acetyl sugar methacrylate 2 was used instead of acetyl sugar methacrylate 1 in the synthesis of random copolymer of styrene-methyl methacrylate-acetyl sugar methacrylate 1. The structures of the constitutional units (a), (b), and (c) contained in copolymer 7 are as follows.

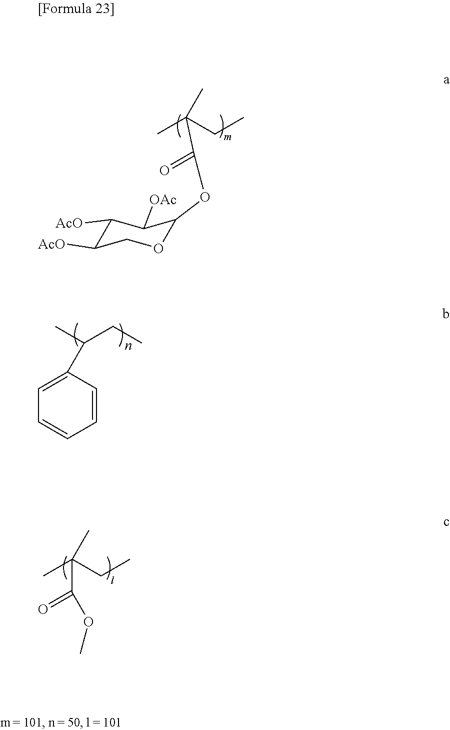

### <Synthesis of Copolymer 8>

### (Synthesis of Acetyl Sugar Acrylate)

10.0 g of acetyl sugar acrylate was synthesized in the same manner as in the synthesis of acetyl sugar methacrylate 2 except that 1.3 g of acryloyl chloride (manufactured by Tokyo Chemical Industry Co., Ltd.) was used instead of 1.4 g of methacryloyl chloride in the synthesis of acetyl sugar methacrylate 2. The structure of the obtained acetyl sugar acrylate is as follows.

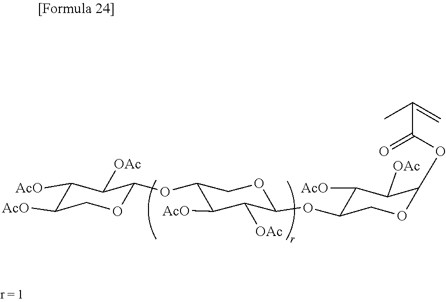

### (Synthesis of Random Copolymer of Styrene-Methyl Methacrylate-Acetyl Sugar Acrylate)

Copolymer 8 was synthesized in the same manner as in the synthesis of random copolymer of styrene-methyl methacrylate-acetyl sugar methacrylate 1 except that acetyl sugar acrylate was used instead of acetyl sugar methacrylate 1 in the synthesis of random copolymer of styrene-methyl methacrylate-acetyl sugar methacrylate 1. The structures of the constitutional units (a), (b), and (c) contained in copolymer 8 are as follows.

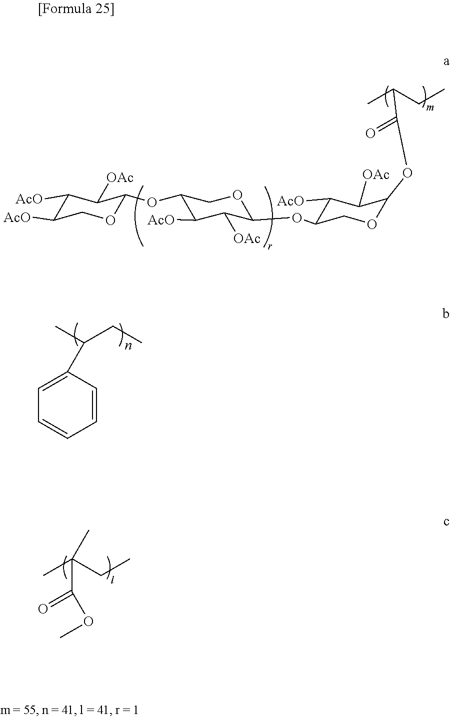

### <Synthesis of Copolymer 9>

### (Synthesis of Sugar Methacrylate)

33 g of xylooligosaccharide (average degree of polymerization: 4) was dissolved in 150 mL of water, 28.5 g of ammonium hydrogen carbonate (manufactured by Wako Pure Chemical Industries, Ltd.) was added 4 times every 24 hours, and the mixture was stirred at 37° C. for % hours. Subsequently, 200 mL of distilled water was added, the water was distilled off until a volume of 20 mL was reached, and then 150 mL of water was added, and the mixture was concentrated until a volume of 10 mL was reached. This was repeated until the ammonia odor disappeared, and after freeze-drying, a white solid was obtained. The resulting material was dissolved in 50 mL of a 1×10⁻³ M KOH aqueous solution, 10.4 g of 2-isocyanatoethyl methacrylate (manufactured by Wako Pure Chemical Industries, Ltd.) was added, and the mixture was vigorously stirred for 12 hours while being kept at 3° C. After removing the precipitated white solid, the filtrate was washed 4 times with 50 mL of diethyl ether and freeze-dried. Then, the obtained white solid was dissolved in a mixed solution of 2 mL of water and 10 mL of methanol, and the solution was dropped into a mixed solution of 200 mL of acetone and cooled. Thereafter, it was filtered by a filter and dried under reduced pressure, thereby obtaining sugar methacrylate. The structure of the obtained sugar methacrylate is as follow s.

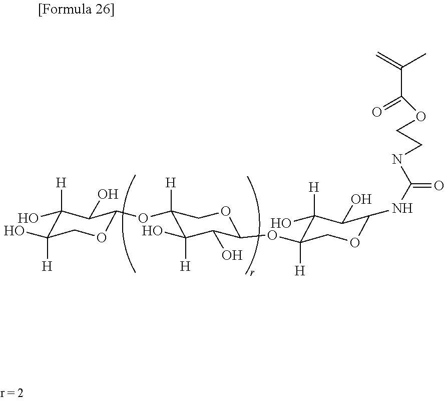

### (Synthesis of Random Copolymer of Styrene-Methyl Methacrylate-Sugar Methacrylate)

Copolymer 9 was synthesized in the same manner as in the synthesis of random copolymer of styrene-methyl methacrylate-acetyl sugar methacrylate 1 except that sugar methacrylate was used instead of acetyl sugar methacrylate 1 in the synthesis of random copolymer of styrene-methyl methacrylate-acetyl sugar methacrylate 1. The structures of the constitutional units (a), (b), and (c) contained in copolymer 9 are as follows.

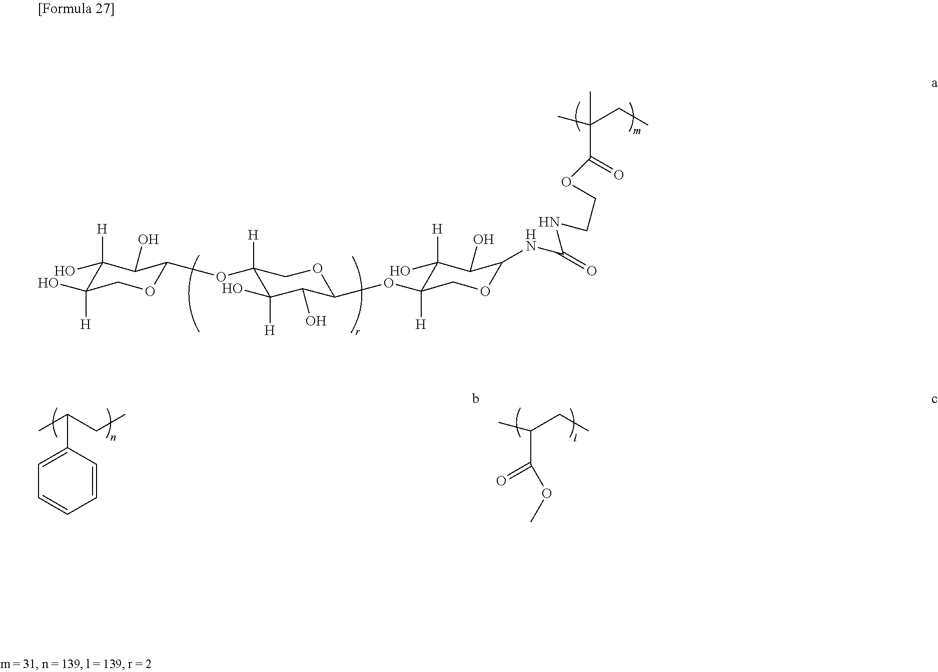

### <Synthesis of Copolymer 10>

### (Synthesis of Acetyl Sugar Methacrylate 3)

120 g of acetic anhydride was reacted with 10 g of sugar methacrylate for 2 hours. Then, the reaction was terminated with a 33% magnesium acetate solution, and pure water was added to cause precipitation, thereby obtaining acetyl sugar methacrylate 3. The structure of the obtained acetyl sugar methacrylate 3 is as follows.

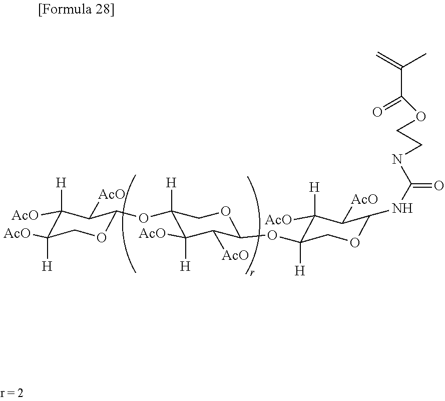

### (Synthesis of Random Copolymer of Styrene-Methyl Methacrylate-Acetyl Sugar Methacrylate 3)

Copolymer 10 was synthesized in the same manner as in the synthesis of random copolymer of styrene-methyl methacrylate-acetyl sugar methacrylate 1 except that acetyl sugar methacrylate 3 was used instead of acetyl sugar methacrylate 1 in the synthesis of random copolymer of styrene-methyl methacrylate-acetyl sugar methacrylate 1. The structures of the constitutional units (a), (b), and (c) contained in copolymer 10 are as follows.

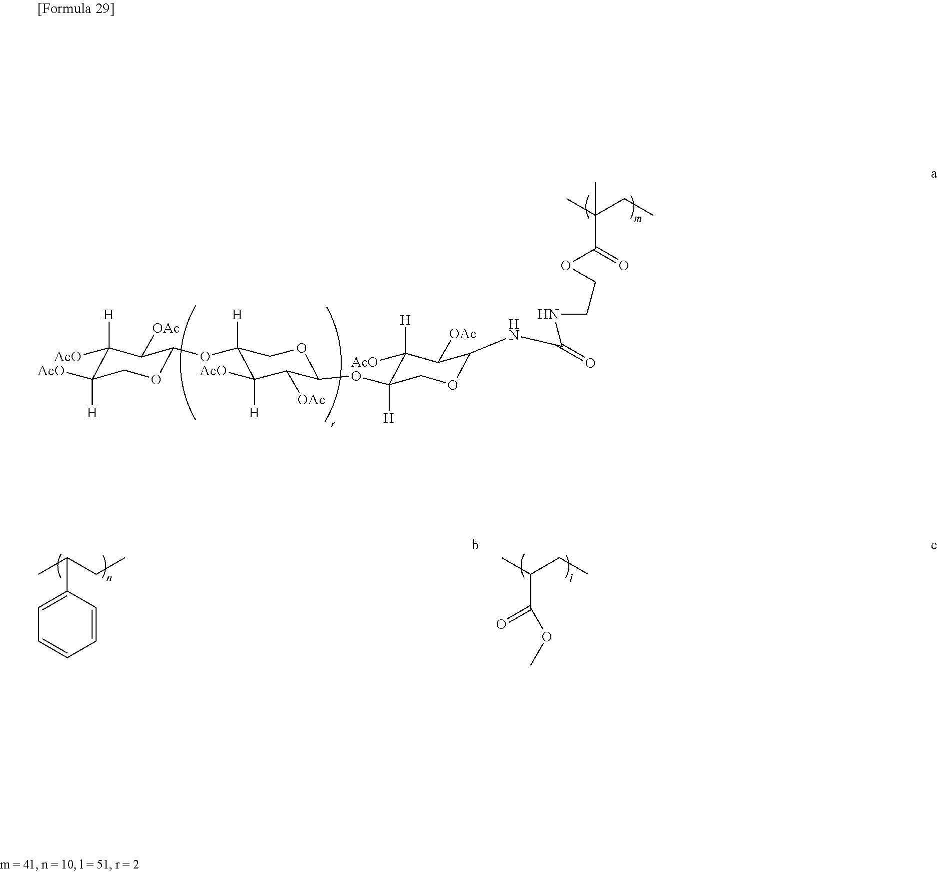

### <Synthesis of Copolymer 11>

### (Synthesis of Acetyl Sugar Ethyl Methacrylate 1)

1.1 g of acetyl sugar ethyl methacrylate was synthesized in the same manner as in the synthesis of acetyl sugar methacrylate 1 except that 1.8 g of 1-chloroethyl methacrylate (manufactured by Alfa Aesar) was used instead of 1.4 g of methacryloyl chloride in the synthesis of acetyl sugar methacrylate 1. The structure of the obtained acetyl sugar ethyl methacrylate is as follows.

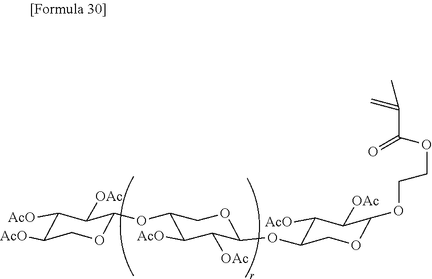

### (Synthesis of Random Copolymer of Styrene-Methyl Methacrylate-Acetyl Sugar Ethyl Methacrylate)

Copolymer 11 was synthesized in the same manner as in the synthesis of random copolymer of styrene-methyl methacrylate-acetyl sugar methacrylate 1 except that acetyl sugar ethyl methacrylate was used instead of acetyl sugar methacrylate 1 in the synthesis of random copolymer of styrene-methyl methacrylate-acetyl sugar methacrylate 1. The structures of the constitutional units (a), (b), and (c) contained in copolymer 11 are as follows.

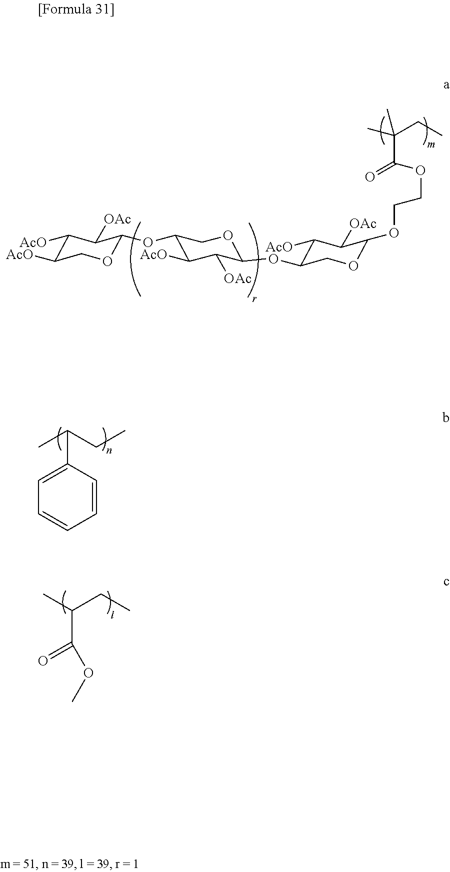

### <Synthesis of Copolymer 12>

### (Synthesis of Acetyl Sugar Methacrylate 4)

Acetyl sugar methacrylate 4 was synthesized in the same manner as in the synthesis of acetyl sugar methacrylate 1 except that glucose was used instead of xylooligosaccharide having an average degree of polymerization of 3 in the synthesis of acetyl sugar methacrylate 1. The structure of the obtained acetyl sugar methacrylate 4 is as follows.

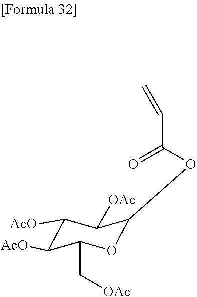 [SMILES: C=CC(=O)OC1OC(COC(C)=O)C(OC(C)=O)C(OC(C)=O)C1OC(C)=O]

### (Synthesis of Random Copolymer of Styrene-Methyl Methacrylate-Acetyl Sugar Methacrylate 4)

Copolymer 12 was synthesized in the same manner as in the synthesis of random copolymer of styrene-methyl methacrylate-acetyl sugar methacrylate 1 except that acetyl sugar methacrylate 4 was used instead of acetyl sugar methacrylate 1 in the synthesis of random copolymer of styrene-methyl methacrylate-acetyl sugar methacrylate 1. The structures of the constitutional units (a), (b), and (c) contained in copolymer 12 are as follows.

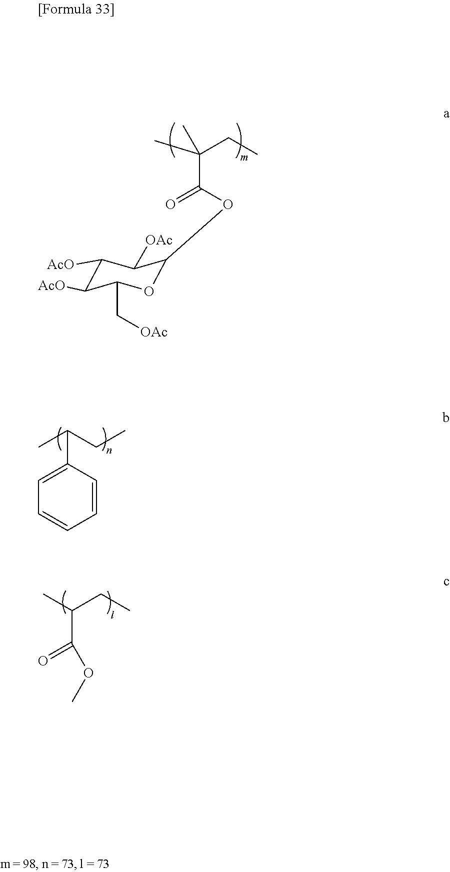

### <Synthesis of Copolymer 13>

### (Synthesis of Acetyl Sugar Styrene)

Acetyl sugar was synthesized in the same manner as in the synthesis of acetyl sugar methacrylate 1. Then, 10.8 g (90 mmol) of 4-vinylphenol, 32.2 g (32 mmol) of acetyl sugar, and 0.5 g of zinc chloride w ere stirred and heated at 160° C. for 30 minutes in a silicon oil bath. The molten mixture was cooled to about 60° C. and dissolved in 200 mL of benzene. This solution was washed twice with water, then with 1M sodium hydroxide until the aqueous phase became almost colorless, then twice with water, dried, and concentrated under reduced pressure, thereby obtaining 26.5 g of acetyl sugar styrene. The structure of the obtained acetyl sugar styrene is as follows.

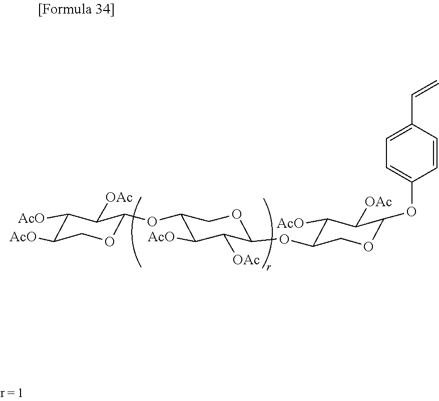

### (Synthesis of Random Copolymer of Styrene-Methyl Methacrylate-Acetyl Sugar Styrene)

Copolymer 13 was synthesized in the same manner as in the synthesis of random copolymer of styrene-methyl methacrylate-acetyl sugar methacrylate 1 except that acetyl sugar styrene was used instead of acetyl sugar methacrylate 1 in the synthesis of random copolymer of styrene-methyl methacrylate-acetyl sugar methacrylate 1. The structures of the constitutional units (a), (b), and (c) contained in copolymer 13 are as follows.

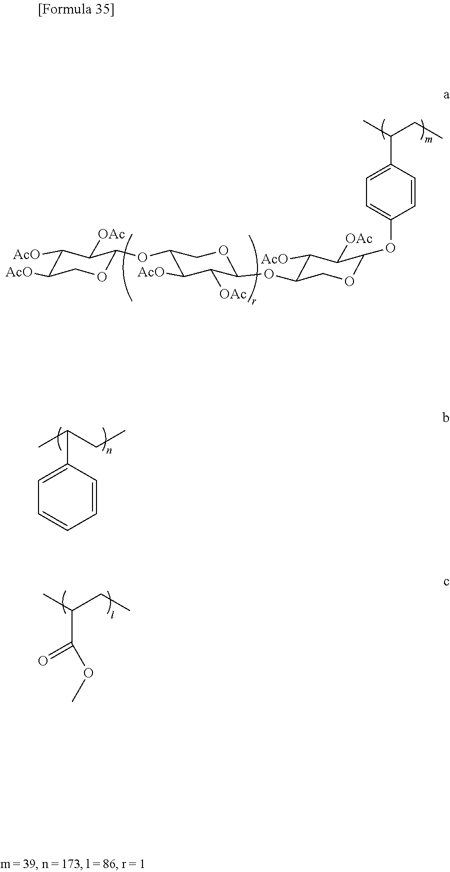

### <Synthesis of Copolymer 14>

### (Synthesis of Random Copolymer of Styrene-Glycidyl Methacrylate-Acetyl Sugar Methacrylate 1)

Copolymer 14 was synthesized in the same manner as in the synthesis of random copolymer of styrene-methyl methacrylate-acetyl sugar methacrylate 1 except that glycidyl methacrylate (manufactured by Tokyo Chemical Industry Co., Ltd.) was used instead of methyl methacrylate in the synthesis of random copolymer of styrene-methyl methacrylate-acetyl sugar methacrylate 1. The structures of the constitutional units (a), (b), and (c) contained in copolymer 14 are as follows.

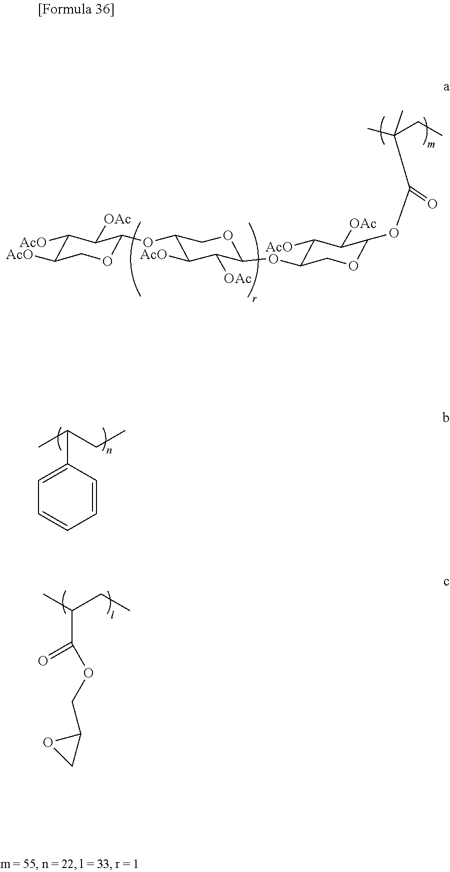

### <Synthesis of Copolymer 15>

### (Synthesis of Random Copolymer of Styrene-Acetyl Sugar Methacrylate 1)

Copolymer 15 was synthesized in the same manner as in the synthesis of random copolymer of styrene-methyl methacrylate-acetyl sugar methacrylate 1 except that methyl methacrylate was not used in the synthesis of random copolymer of styrene-methyl methacrylate-acetyl sugar methacrylate 1. The structures of the constitutional units (a) and (b) contained in copolymer 15 are as follows.

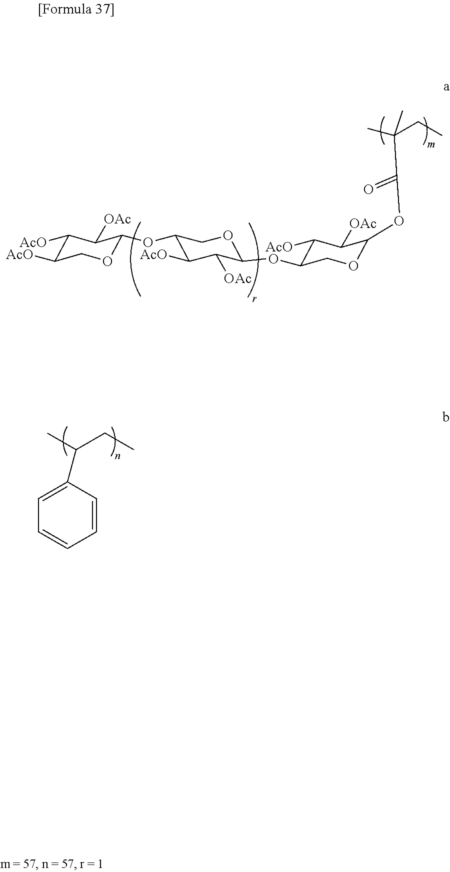

### <Synthesis of Copolymer 16>

### (Synthesis of Random Copolymer of Methyl Methacrylate-Acetyl Sugar Methacrylate 1)

Copolymer 16 was synthesized in the same manner as in the synthesis of random copolymer of styrene-methyl methacrylate-acetyl sugar methacrylate 1 except that styrene was not used in the synthesis of random copolymer of styrene-methyl methacrylate-acetyl sugar methacrylate 1. The structures of the constitutional units (a) and (c) contained in copolymer 16 are as follows.

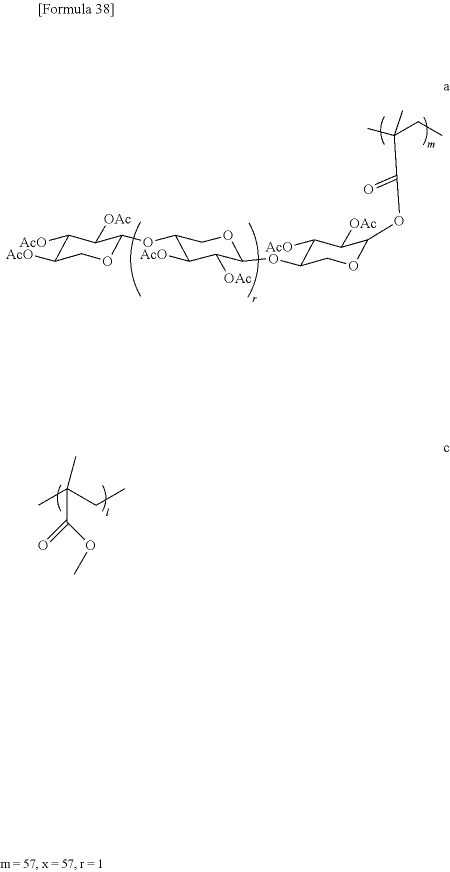

### <Synthesis of Copolymer 17>

### (Synthesis of Random Copolymer of Styrene-Methyl Methacrylate)

Copolymer 17 was synthesized in the same manner as in the synthesis of random copolymer of styrene-methyl methacrylate-acetyl sugar methacrylate 1 except that acetyl sugar methacrylate 1 was not used in the synthesis of random copolymer of styrene-methyl methacrylate-acetyl sugar methacrylate 1. The structures of the constitutional units (b) and (c) contained in copolymer 17 are as follows.

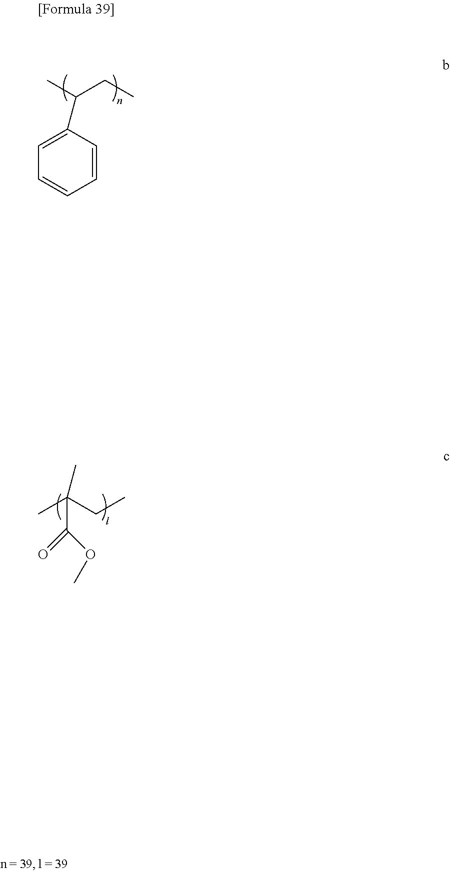

### [Copolymer Analysis]

### <Weight Average Molecular Weight>

The weight average molecular weights of the copolymers were measured by a gel permeation chromatogram (GPC) method.

GPC Column: Shodex K-806M/K-802 Connected column (SHOWA DENKO K.K.) Column temperature: 40° C.
Mobile phase: Chloroform

### Detector: RI

The degree of polymerization was confirmed by the GPC method after polymerization was completed, thereby confirming that a random copolymer having a degree of polymerization and an average molecular weight as desired was formed. Regarding the molecular weight of each polymer, the weight average molecular weight Mw was 50,000.

<Ratio of Unit (a):Unit (b):Unit (c)>

The ratio (mass ratio) of each copolymer was determined and calculated by ¹H-NMR.

<Content of Units Derived from Sugar Derivative>

The content of units derived from a sugar derivative was calculated by the following equation.

Content of units derived from sugar derivative (% by mass)=Mass of units derived from sugar derivative×Number of units (monomer) derived from sugar derivative/Weight average molecular weight of copolymer

The number of units (monomers) containing a sugar derivative was calculated from the weight average molecular weight of a copolymer, the constitutional unit ratio of each structure calculated by NMR, and the molecular weight of each unit.

TABLE 1

| | | | | | Content of sugar |
|---|---|---|---|---|---|
| | | | | Mass ratio | derivative units |
| | Unit (a) | Unit (b) | Unit (c) | a:b:c | (% by mass) |
| Copolymer 1 | Acetyl sugar methactylate 1 | Styrene | Methyl methacrylate | 50:20:30 | 78 |
| Copolymer 2 | Acetyl sugar methacrylate 1 | Styrene | Butyl acrylate | 30:50:30 | 66 |
| Copolymer 3 | Acetyl sugar methacrylate 1 | Styrene | Methyl acrylate | 40:30:30 | 75 |
| Copolymer 4 | Acetyl sugar methacrylate 1 | Naphthalene | Methyl methacrylate | 50:10:40 | 77 |
| Copolymer 5 | Acetyl sugar methacrylate 1 | Styrene | Hydroxyethyl methacrylate | 40:30:30 | 72 |
| Copolymer 6 | Acetyl sugar methacrylate 1 | Styrene | Acrylic acid | 40:30:30 | 76 |
| Copolymer 7 | Acetyl sugar methacrylate 2 | Styrene | Methyl methacrylate | 40:20:40 | 52 |
| Copolymer 8 | Acetyl sugar acrylate | Styrene | Methyl methacrylate | 40:30:30 | 75 |
| Copolymer 9 | Sugar methacrylate) | Styrene | Methyl methacrylate | 10:45:45 | 32 |
| Copolymer 10 | Acetyl sugar methacrylate 3 | Styrene | Methyl methacrylate | 40:10:50 | 73 |
| Copolymer 11 | Acetyl sugar hydroxy methacrylate | Styrene | Methyl methacrylate | 40:30:30 | 72 |
| Copolymer 12 | Acetyl sugar methacrylate 4 | Styrene | Methyl methacrylate | 40:30:30 | 39 |
| Copolymer 13 | Acetyl sugar styrene | Styrene | Methyl methacrylate | 10:60:30 | 53 |
| Copolymer 14 | Acetyl sugar styrene | Styrene | Glycidyl methacrylate | 50:20:30 | 77 |
| Copolymer 15 | Acetyl sugar methacrylate 1 | Styrene | None | 50:50:0 | 78 |
| Copolymer 16 | Acetyl sugar methacrylate 1 | None | Methyl methacrylate | 50:0:50 | 78 |
| Copolymer 17 | None | Styrene | Methyl methacrylate | 0:50:50 | 0 |

### [Evaluation of Copolymer]

### <Calculation of Copolymer Solubility>

0.1 g of each weighed copolymer was placed in a sample bottle and stirred while gradually adding PGMEA as an organic solvent (up to 19.9 g of the organic solvent). The liquid temperature of the organic solvent was set to 25° C. It was considered that the solution was dissolved when the solution became transparent, and the copolymer solubility was calculated from the mass of the added organic solvent.

Copolymer solubility (% by mass)=Mass of copolymer/Mass of organic solvent when dissolved×100

The obtained results are shown in Table 3 below. The copolymer solubility was evaluated to be favorable at 2% or more.

### Examples 1 to 19 and Comparative Examples 1 to 3

### <Preparation of Underlayer Film-Forming Composition Sample>

50 mg of each copolymer was dissolved in 1 mL of PGMEA to obtain an underlayer film-forming composition sample of each of the Examples and Comparative Examples. When a catalyst was added, it was added such that the solid content of the catalyst was 3% by mass with respect to the total mass of the copolymer. Types of catalysts added are as follows.

Catalyst 1: Bis(t-butylsulfonyl)diazomethane (manufactured by Wako Pure Chemical Industries, Ltd.)
Catalyst 2: p-toluenesulfonic acid (manufactured by Tokyo Chemical Industry Co., Ltd.)
Catalyst 3: Bis(cyclohexylsulfonyl)diazomethane (manufactured by Wako Pure Chemical Industries, Ltd.)

### <Evaluation of Metal Introduction Rate of Underlayer Film-Forming Composition>

Each obtained underlayer film-forming composition was spin-coated on a 2-inch silicon wafer substrate. After spin-coating was performed to result in a film thickness of 200 nm, each coating was baked at 230° C. for 5 minutes on a hot plate to form an underlayer film sample.

The underlayer film samples thus formed were placed in an ALD (atomic layer deposition apparatus, manufactured by PICUSAN, SUMALE R-100B), Al(CH₃)₃ gas was introduced thereinto at 95° C., and then, steam was introduced thereinto. By repeating this operation three times, Al was introduced into the underlayer film.

EDX analysis (energy dispersive X-ray analysis) was performed on each underlayer film sample after introduction of Al by using an electron microscope JSM7800F (manufactured by JEOL Ltd.) to calculate an Al component ratio (Al content). The Al content was evaluated to be favorable at 5 at % or more.

### <Calculation of Proportion of Residual Underlayer Film>

The obtained underlayer film-forming composition was spin-coated on a 2-inch silicon wafer substrate. After spin-coating was performed to result in a film thickness of 200 nm, each coating was baked at 210° C. for 2 minutes on a hot plate to form an underlayer film sample.

1 ml of a 50:50 (mass ratio) mixture of propylene glycol monomethyl ether acetate and propylene glycol monomethyl ether, which is a solvent used for photoresist, was applied to the underlayer film sample before washing with a spin coater at 1000 rpm for 30 seconds, and washed. Then, it was baked at 180° C. for 2 minutes in the atmosphere on a hot plate, thereby obtaining a washed underlayer film.

The underlayer film thickness before and after washing was measured with a profiler, and the proportion of the residual underlayer film was determined as follows.

Proportion of residual underlayer film (%)=Underlayer film thickness after washing (μm)/Underlayer film thickness before washing (μm)*100

The proportion of the residual underlayer film was evaluated to be favorable at 90% or more.

### <UV Reflectivity>

The obtained underlayer film-forming composition was spin-coated on a 2-inch silicon wafer substrate. After spin-coating was performed to result in a film thickness of 200 nm, each coating was baked at 210° C. for 2 minutes on a hot plate to form an underlayer film sample.

The obtained underlayer film sample was set on a spectrophotometer (V770EX, manufactured by JASCO Corporation) equipped with an integrating sphere, and the reflectivity at a wavelength of 193 nm was measured and used as the ultraviolet reflectivity. The UV reflectivity was evaluated to be favorable at 50% or less.

### <Evaluation of Etching Workability>

The obtained underlayer film-forming composition was spin-coated on a 2-inch silicon wafer substrate. After spin-coating was performed to result in a film thickness of 200 nm, each coating was baked at 210° C. for 2 minutes on a hot plate to form an underlayer film sample.

After coating and heating the ArF resist, masking was performed using an ArF excimer laser exposure machine so as to create a line-and-space (line width: 50 nm; space width: 50 nm) shape, and exposure was performed. Then, each sample was immersed in a developer after baking at 60° C. for 1 minute on a hot plate, thereby forming a line-and-space pattern. Each substrate was subjected to oxygen plasma treatment (100 sccm, 4 Pa, 100 W, 300 seconds) with an ICP plasma etching apparatus (manufactured by Tokyo Electron Limited) to remove the photoresist, thereby forming a line-and-space pattern in the underlayer film. Then, a metal was introduced into the underlayer film sample in the same manner as in the evaluation of the metal introduction rate of the underlayer film-forming composition. Using this pattern as a mask, each silicon substrate was etched using hexafluoroethane gas.

The patterned surface of each substrate treated with trifluoromethane was observed with a scanning electron microscope (SEM) JSM7800F (manufactured by JEOL Ltd.) at an acceleration voltage of 1.5 kV, an emission current of 37.0 μA, and a magnification of 100,000 times. Thai, the state of etching workability was confirmed. The state of etching workability was evaluated according to the following evaluation criteria.

O The pattern is in a state where there is no line collapse in one field of view of SEM.
x: The pattern is observed with line collapse, even partially, or the pattern has a distorted structure.

TABLE 2

| | | | | Proportion | | | |
|---|---|---|---|---|---|---|---|
| | | | | of residual | UV | Al | |
| | | | Solubility | underlayer film | reflectivity | content | Etching |
| | Copolymer | Catalyst | (%) | (%) | (%) | (at %) | workability |
| Example 1 | Copolymer 1 | — | 5.1 | 95 | 17 | 25 | ∘ |
| Example 2 | Copolymer 2 | — | 7.9 | 92 | 14 | 15 | ∘ |
| Example 3 | Copolymer 3 | — | 13.0 | 90 | 17 | 24 | ∘ |
| Example 4 | Copolymer 4 | — | 3.4 | 98 | 45 | 20 | ∘ |
| Example 5 | Copolymer 5 | — | 2.2 | 91 | 20 | 14 | ∘ |
| Example 6 | Copolymer 6 | — | 2.1 | 90 | 32 | 19 | ∘ |
| Example 7 | Copolymer 7 | — | 8.1 | 94 | 29 | 8 | ∘ |
| Example 8 | Copolymer 8 | — | 11.0 | 94 | 21 | 23 | ∘ |
| Example 9 | Copolymer 9 | — | 2.0 | 95 | 18 | 10 | ∘ |
| Example 10 | Copolymer 10 | — | 3.4 | 96 | 36 | 12 | ∘ |
| Example 11 | Copolymer 11 | — | 2.8 | 93 | 19 | 20 | ∘ |
| Example 12 | Copolymer 12 | — | 2.0 | 96 | 15 | 15 | ∘ |
| Example 13 | Copolymer 13 | — | 2.2 | 93 | 14 | 9 | ∘ |
| Example 14 | Copolymer 14 | — | 10.0 | 96 | 18 | 24 | ∘ |
| Example 15 | Copolymer 1 | Catalyst 1 | 5.1 | 96 | 17 | 22 | ∘ |
| Example 16 | Copolymer 14 | Catalyst 1 | 10.0 | 100 | 18 | 24 | ∘ |
| Example 17 | Copolymer 14 | Catalyst 2 | 10.0 | 100 | 19 | 24 | ∘ |
| Example 18 | Copolymer 1 | Catalyst 3 | 5.1 | 98 | 19 | 24 | ∘ |
| Example 19 | Copolymer 14 | Catalyst 3 | 10.0 | 99 | 19 | 24 | ∘ |
| Comparative | Copolymer 15 | | 1.5 | 30 | 55 | 22 | ∘ |
| Example 1 | | | | | | | |
| Comparative | Copolymer 16 | | 3.0 | 45 | 90 | 20 | x |
| Example 2 | | | | | | | |
| Comparative | Copolymer 17 | | 10.0 | 90 | 30 | 4 | x |
| Example 3 | | | | | | | |

As shown in Table 2, each of the underlayer film-forming composition in the Examples showed high levels of solubility of the copolymer in the organic solvent. Further, each of the underlayer film-forming compositions in the Examples had very low reflectivity of UV used for exposure for a photoresist, and an underlayer film having a high proportion of the residual underlayer film could be formed under the atmosphere and at a relatively low temperature. In each of the Examples, the metal introduction rate was high, and the etching workability was favorable.

Meanwhile, in Comparative Example 1, the solubility of the copolymer in the organic solvent was low; and the proportion of the residual underlayer film was low. In Comparative Example 2, the proportion of the residual underlayer film was low, and the etching workability was also poor. In Comparative Example 3, the metal introduction rate was extremely small, and the etching workability was not favorable. Further, the underlayer films obtained in Comparative Examples 1 to 3 had high UV reflectivity;

### REFERENCE SIGNS LIST

10 Substrate
20 Underlayer film

1. An underlayer film-forming composition, which contains a copolymer and an organic solvent and is used for patterning,
wherein the copolymer contains:
(a) a unit derived from a sugar derivative;
(b) a unit derived from a compound having a light antireflection function; and
(c) a unit derived from a compound capable of cross-coupling the copolymer,
the unit derived from a sugar derivative (a) is at least one selected from a unit derived from a pentose derivative and a unit derived from a hexose derivative, and
the underlayer film-forming composition is for metal introduction.

2. The underlayer film-forming composition according to claim 1, wherein the unit derived from a compound having a light antireflection function (b) is a unit derived from an aromatic ring-containing compound, and the unit derived from a compound capable of cross-coupling the copolymer (c) is a unit derived from a (meth)acrylate.

3. The underlayer film-forming composition according to claim 1, wherein the unit derived from a sugar derivative (a) is at least one selected from a unit derived from a cellulose derivative, a unit derived from a hemicellulose derivative, and a unit derived from a xylooligosaccharide derivative.

4. The underlayer film-forming composition according to claim 2, wherein the unit derived from an aromatic ring-containing compound is at least one selected from a unit derived from a benzene ring-containing compound and a unit derived from a naphthalene ring-containing compound.

5. The underlayer film-forming composition according to claim 2, wherein the unit derived from a (meth)acrylate has at least one selected from an alkyl group which may have a substituent and an aryl group which may have a substituent.

6. The underlayer film-forming composition according to claim 2, wherein the unit derived from a (meth)acrylate has an alkyl group which may have a substituent, and the alkyl group has 1 to 8 carbon atoms.

7. A pattern-forming method, comprising:
forming an underlayer film using the underlayer film-forming composition according to claim 1.

8. The pattern-forming method according to claim 7, comprising:
introducing a metal into the underlayer film.

9. A copolymer containing: (a) a unit derived from a sugar derivative;
(b) a unit derived from a compound having a light antireflection function; and
(c) a unit derived from a compound capable of cross-coupling the copolymer,
wherein the unit derived from a sugar derivative (a) is at least one selected from a unit derived from a pentose derivative and a unit derived from a hexose derivative.

10. The copolymer according to claim 9, wherein the unit derived from a compound having a light antireflection function (b) is a unit derived from an aromatic ring-containing compound, and the unit derived from a compound capable of cross-coupling the copolymer (c) is a unit derived from a (meth)acrylate.

11. A monomer for an underlayer film-forming composition, which is represented by the following formula (1′) or the following formula (2′): 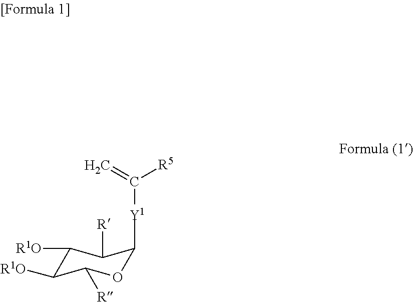
wherein, in formula (1′), each R¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R¹ may be the same or different;
R′ represents a hydrogen atom, —OR¹¹, or —NR¹²₂;
R″ represents a hydrogen atom, —OR¹¹, —COOR¹³, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group;
R⁵ represents a hydrogen atom or an alkyl group; and
each Y¹ independently represent a single bond or a linking group; 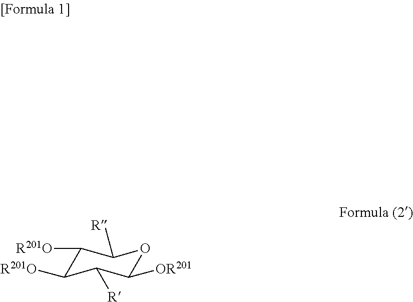
wherein, in formula (2′), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different;
R′ represents a hydrogen atom, —OR¹¹, or —NR¹²₂; and
R″ represents a hydrogen atom, —OR¹¹, —COOR¹³, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group.
